(19) United States
(12) Patent Application Publication
(10) Pub. No.: US 2025/0364450 A1
(43) Pub. Date: Nov. 27, 2025

(54) SEMICONDUCTOR DIE PACKAGE AND METHODS OF FORMATION

(71) Applicant: Taiwan Semiconductor Manufacturing Company , Ltd., Hsinchu (TW)

(72) Inventor: Wen-Shiang LIAO, Toufen Township (TW)

(21) Appl. No.: 19/292,114

(22) Filed: Aug. 6, 2025

Related U.S. Application Data
(62) Division of application No. 18/156,847, filed on Jan. 19, 2023.
(60) Provisional application No. 63/383,155, filed on Nov. 10, 2022.

(51) Int. Cl. H01L 23/66; H01L 21/02; H01L 23/495; H01L 23/522; H01P 3/16

(52) U.S. Cl. CPC H01L 23/66; H01L 21/02266; H01L 23/49575; H01L 23/5226; H01P 3/16; H01L 2223/6627

(57) ABSTRACT

Semiconductor dies in a semiconductor die package may communicate through a dielectric waveguide. The dielectric waveguide may include a high dielectric constant (high-k) core layer that is sandwiched by low dielectric constant (low-k) cladding layers. The difference in dielectric constants of the high-k core layer and the low-k cladding layers enables loose coupling of electromagnetic signal modes in the dielectric waveguide while providing a relatively low critical angle for achieving total internal reflections in the high-k core layer. Thus, the combination of semiconductor die package techniques described herein and the dielectric waveguide described herein may enable increased inter-die communication bandwidth while achieving a reduced footprint and increased density for semiconductor die packages.

### CROSS-REFERENCE TO RELATED APPLICATION

This application is a division of U.S. patent application Ser. No. 18/156,847, filed Jan. 19, 2023, which claims the benefit of U.S. patent application Ser. No. 63/383,155, filed Nov. 10, 2022, entitled “SEMICONDUCTOR DIE PACKAGE AND METHODS OF FORMATION,” the contents of which are incorporated herein by reference in their entireties.

### BACKGROUND

Various semiconductor device packing techniques may be used to incorporate one or more semiconductor dies into a semiconductor device package. In some cases, semiconductor dies may be stacked in a semiconductor device package to achieve a smaller horizontal or lateral footprint of the semiconductor device package and/or to increase the density of the semiconductor device package. Semiconductor device packing techniques that may be performed to integrate a plurality of semiconductor dies in a semiconductor device package may include integrated fanout (InFO), package on package (POP), chip on wafer (CoW), system on integrated chips (SoIC), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor die package described herein.

FIGS. 3A and 3B are diagrams of an example implementation of a dielectric waveguide structure described herein.

FIGS. 4A-4C are diagrams of an example implementation of a dielectric waveguide structure described herein.

FIG. 5 is a diagram of an example implementation of a dielectric waveguide structure described herein.

FIGS. 6A-6N are diagrams of an example implementation of forming a portion of a semiconductor die package described herein.

FIG. 7 is a diagram of example components of a device described herein.

FIG. 8 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor dies in a semiconductor die package may communicate through various interconnects, conductive traces, and/or other electrically conductive layers. In some cases, an inter-die communication link in the semiconductor die package may occupy large amounts of area in the semiconductor die package and/or may not support high bandwidth inter-die communications. As a result, the semiconductor die package may not be suitable for small form factor applications and/or high-bandwidth applications such as telecommunications (e.g., smartphones and other hand-held devices), Internet of things (IoT) devices, and/or personal computing devices (e.g., tablet computers, wearable devices).

Some implementations described herein provide a wafer on wafer (WoW) semiconductor die package in which semiconductor dies are directly bonded such that the semiconductor dies are vertically arranged in the WoW semiconductor die package. The use of direct bonding and vertical stacking of dies may reduce interconnect lengths between the semiconductor dies (which reduces power loss and signal propagation times) and may enable increased density of semiconductor die packages in a semiconductor device package that includes the WOW semiconductor die package.

As further described herein, semiconductor dies in the WoW semiconductor die package may communicate through a dielectric waveguide. The dielectric waveguide may include a high dielectric constant (high-k) core layer that is sandwiched by low dielectric constant (low-k) cladding layers. The difference in dielectric constants of the high-k core layer and the low-k cladding layers enables loose coupling of electromagnetic signal modes in the dielectric waveguide while providing a relatively low critical angle for achieving total internal reflections in the high-k core layer. Thus, the combination of WoW semiconductor die package techniques described herein and the dielectric waveguide described herein may enable increased inter-die communication bandwidth (e.g., approximately 10 gigahertz (GHz) bandwidth or greater) while achieving a reduced footprint and increased density for semiconductor die packages. The increased inter-die communication bandwidth may support high-speed and/or high-bandwidth applications, such as data center communications, millimeter wave telecommunications (e.g., fifth generation (5G) telecommunications, sixth generation (6G) telecommunications, or a later generation of telecommunications), autonomous driving, IoT, and/or artificial intelligence, among other examples.

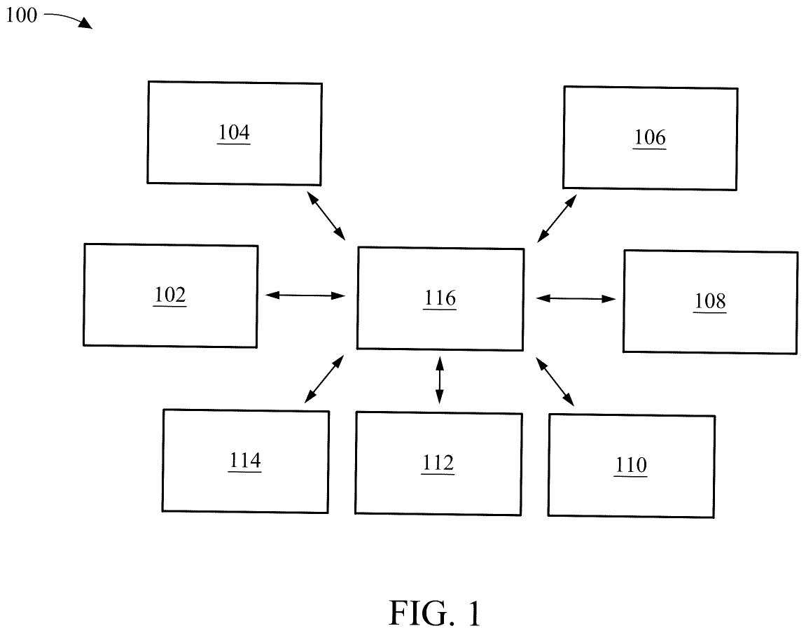

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may include a hybrid bonding tool. A hybrid bonding tool is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

In some implementations, one or more of the semiconductor processing tools 102-114 and/or the wafer/die transport tool 116 may perform one or more semiconductor processing operations described herein. For example, one or more of the semiconductor processing tools 102-114 and/or the wafer/die transport tool 116 may bond a first semiconductor die with a second semiconductor die; may bond a third semiconductor die to the first semiconductor die on a same side of the first semiconductor die as the second semiconductor die; may form a first low-k dielectric layer above the second semiconductor die and the third semiconductor die; may form a high-k dielectric layer on the first low-k dielectric layer; may etch the high-k dielectric layer to remove first portions of the high-k dielectric layer; and/or may form a second low-k dielectric layer on a remaining portion of the high-k dielectric layer and on portions of the first low-k dielectric layer that are not covered by the remaining portion of the high-k dielectric layer, as described herein.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

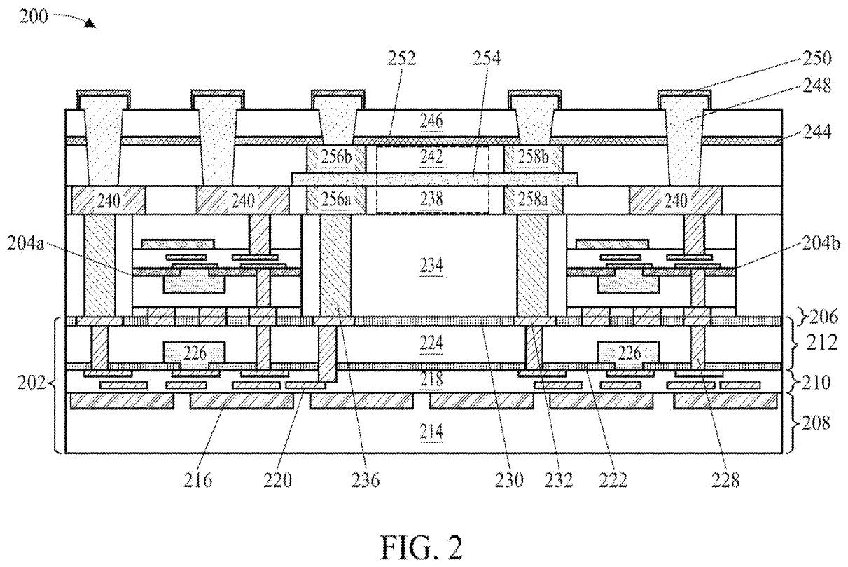

FIG. 2 is a diagram of an example semiconductor die package 200 described herein. The semiconductor die package 200 includes an example of a wafer on wafer (WoW) semiconductor die package, a system on integrated chips (SoIC) semiconductor die package, or another type of semiconductor die package in which semiconductor dies are directly bonded and vertically arranged or stacked. FIG. 2 illustrates a cross-section view of a portion of the semiconductor die package 200.

As shown in FIG. 2, the semiconductor die package 200 may include a plurality of semiconductor dies, such as a semiconductor die 202, a semiconductor die 204a, and a semiconductor die 204b, among other examples. The semiconductor die 204a may be located above and/or over the semiconductor die 202. Thus, the semiconductor die 202 and the semiconductor die 204a may be vertically adjacent in the semiconductor die package 200. The semiconductor die 204b may be located above and/or over the semiconductor die 202. Thus, the semiconductor die 202 and the semiconductor die 204b may be vertically adjacent in the semiconductor die package 200.

The semiconductor die 204a and the semiconductor die 204b may each be bonded with the semiconductor die 202 at a bonding interface 206. The bonding interface 206 may be located on a top side of the semiconductor die 202. The semiconductor die 204a and the semiconductor die 204b may each be bonded with the semiconductor die 202 on a same side of the semiconductor die 202, and may therefore be side by side (or horizontally adjacent) in the semiconductor die package 200. The bonding interface 206 may be a direct bonding interface in that the semiconductor die 204a and the semiconductor die 204b are bonded with the semiconductor die 202 by direct conductive pad to conductive pad bonding.

The semiconductor die 202, the semiconductor die 204a, and the semiconductor die 204b may each include a die, a chip, a chiplet, and/or another type of semiconductor die or semiconductor die package. The semiconductor die 202, the semiconductor die 204a, and the semiconductor die 204b may each include a logic device die, a central processing unit (CPU) die, a graphics processing unit (GPU) die, a mobile phone application processing (AP) die, a system on chip (SoC) die that integrates multiple electronic components into a single die, and/or or a high bandwidth memory (HBM) die, among other examples.

The semiconductor die 202, the semiconductor die 204a, and the semiconductor die 204b may each include a variety of electrical circuits suitable for a particular application or use case. The electrical circuits may include various semiconductor devices such as transistors, capacitors, resistors, and/or diodes, among other examples. In some implementations, the electrical circuits include an oscillator configured to generate high-bandwidth electrical signals for inter-die transmission between the semiconductor die 204a and the semiconductor die 204b.

The semiconductor die 202 may include a plurality of regions, such as a device region 208, a redistribution region 210, and an interconnect region 212, among other examples. The redistribution region 210 may be included over and/or on the device region 208. The interconnect region 212 may be included over and/or on the redistribution region 210.

The device region 208 may include a substrate 214. The substrate 214 may include a semiconductor substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate.

The device region 208 may include one or more semiconductor devices 216 included in the substrate 214. The semiconductor devices 216 may include one or more transistors (e.g., planar transistors, fin field effect transistors (FinFETs), nanosheet transistors (e.g., gate all around (GAA) transistors), memory cells, capacitors, inductors, resistors, pixel sensors, circuits (e.g., integrated circuits (ICs)), and/or another type of semiconductor devices.

The redistribution region 210 may be referred to as a back end of line (BEOL) region of the semiconductor die 202. The redistribution region 210 may include one or more dielectric layers 218, which may include a silicon nitride (SiNₓ), an oxide (e.g., a silicon oxide (SiOₓ) and/or another oxide material), a low-k dielectric material, and/or another type of dielectric material. In some implementations, one or more etch stop layers (ESLs) may be included in between layers of the one or more dielectric layers 218. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The redistribution region 210 may further include metallization layers 220 in the one or more dielectric layers 218. The semiconductor devices 216 in the device region 208 may be electrically connected and/or physically connected with one or more of the metallization layers 220. The metallization layers 220 may include conductive lines, trenches, vias, pillars, interconnects, and/or another type of metallization layers. The metallization layers 220 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 212 may include a plurality of dielectric layers, such as a dielectric layer 222 over and/or on the redistribution region 210 and a dielectric layer 224 over and/or on the dielectric layer 222, among other examples. The dielectric layers 222 and 224 may each include a silicon nitride (SiNₓ), an oxide (e.g., a silicon oxide (SiOₓ) and/or another oxide material), a low-k dielectric material, and/or another type of dielectric material. Conductive pads 226 may be included in the dielectric layer 224 and may be electrically connected and/or physically connected with one or more of the metallization layers 220 in the redistribution region 210. Via structures 228 may extend through the dielectric layers 222 and 224 and may be electrically connected and/or physically connected with one or more of the metallization layers 220 in the redistribution region 210. The conductive pads 226 and the via structures 228 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 212 may include another dielectric layer 230 that is included over and/or on the dielectric layer 224. Conductive pads 232 may be included in the dielectric layer 230. The conductive pads 232 may be electrically connected and/or physically connected with one or more of the via structures 228. The conductive pads 232 may include conductive terminals, conductive pads, conductive pillars, under bump metallization (UBM) structures, and/or another type of contacts. The conductive pads 232 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

A dielectric fill layer 234 is included above and/or over the semiconductor die 202. The dielectric fill layer 234 surrounds the sides of the semiconductor die 204a and the sides of the semiconductor die 204b. The dielectric fill layer 234 provides increased structural rigidity and gap filling in the semiconductor die package 200, and protects the semiconductor dies 202, 204a, and 204b from humidity ingress and other contamination. In some implementations, the dielectric fill layer 234 includes a molding compound, such as a polymer, one or more fillers dispersed in a resin, an epoxy-based resin, and/or another type of insulating material. In some implementations, the dielectric fill layer 234 includes a dielectric material such as a silicon oxide (SiOₓ such as SiO₂), a spin-on glass (SOG), and/or another suitable dielectric material. In some implementations, the dielectric fill layer 234 includes a polymer material such as polybenzoxazole (PBO), a polyimide, a low temperature polyimide (LTPI), an epoxy resin, an acrylic resin, a phenol resin, and/or benzocyclobutene (BCB), among other examples.

The semiconductor die package 200 may include a plurality of through dielectric via (TDV) structures 236 that are included in, and extend through, the dielectric fill layer 234. The TDV structures 236 may be referred to as through dielectric vias in that the TDV structures 236 extend through a dielectric layer (e.g., the dielectric fill layer 234). The TDV structures 236 include vertically elongated conductive structures (e.g., vias, pillars, interconnects) that extend between the semiconductor die 202 and upper layers of the semiconductor die package 200. The TDV structures 236 may extend along sides of the semiconductor die 204a and/or along sides of the semiconductor die 204b. The TDV structures 236 may include one or more conductive materials such as a gold (Au) material, a copper (Cu) material, a silver (Ag) material, a nickel (Ni) material, a tin (Sn) material, and/or a palladium (Pd) material, among other examples.

A low-k dielectric layer 238 may be included over and/or on the semiconductor die 204a, over and/or on the semiconductor die 204b, and/or over and/or on the dielectric fill layer 234. The low-k dielectric layer 238 may include a silicon oxide (SiOₓ such as SiO₂) and/or another suitable dielectric material having a dielectric constant that is less than approximately 4.2. However, other values for the dielectric constant of the low-k dielectric layer 238 are within the scope of the present disclosure.

Conductive structures 240 may be included in the low-k dielectric layer 238. In some implementations, a conductive structure 240 may be electrically connected and/or physically connected with a TDV structure 236. In some implementations, a conductive structure 240 may be electrically connected and/or physically connected with the semiconductor die 204a. In some implementations, a conductive structure 240 may be electrically connected and/or physically connected with the semiconductor die 204b. The conductive structures 240 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

Another low-k dielectric layer 242 may be included over and/or on the low-k dielectric layer 238, and/or over and/or on the conductive structures 240. The low-k dielectric layer 242 may include a silicon oxide (SiOₓ such as SiO₂) and/or another suitable dielectric material having a dielectric constant that is less than approximately 4.2. However, other values for the dielectric constant of the low-k dielectric layer 242 are within the scope of the present disclosure. In some implementations, the low-k dielectric layer 238 and the low-k dielectric layer 242 include the same low-k dielectric material or include the same combination of low-k dielectric materials. In some implementations, the low-k dielectric layer 238 and the low-k dielectric layer 242 include the different low-k dielectric materials or include the different combinations of low-k dielectric materials.

One or more passivation layers may be included over and/or on the low-k dielectric layer 242, such as a passivation layer 244 and a passivation layer 246, among other examples. The passivation layer 244 may be included over and/or on the low-k dielectric layer 242, and the passivation layer 246 may be included over and/or on the passivation layer 244. The passivation layer 244 may include a dielectric material such as a nitride (e.g., a silicon nitride (SiₓN_{y})) and/or an oxide (e.g., a silicon oxide (SiOₓ)), among other examples. The passivation layer 246 may include a polymer material such as polybenzoxazole (PBO), a polyimide, a low temperature polyimide (LTPI), an epoxy resin, an acrylic resin, a phenol resin, and/or benzocyclobutene (BCB), among other examples.

Connection structures 248 may be included in and/or may extend through the layers 242-246. One or more of the connection structures 248 may be electrically connected and/or physically connected with one or more conductive structures 240. The connection structures 248 may include ball grid array (BGA) balls, land grid array (LGA) pads, pin grid array (PGA) pins, and/or another type of conductive terminals. The connection structures 248 may enable the semiconductor die package 200 to be mounted to a circuit board, a socket (e.g., an LGA socket), an interposer or redistribution structure of a semiconductor device package (e.g., a chip on wafer on substrate (CoWoS) package, an integrated fanout (InFO) package), and/or another type of mounting structure.

A treatment layer 250 may be included on the connection structures 248. The treatment layer 250 may include a plating layer or finishing layer that is included to protect the exposed surfaces of the connection structures 248. The treatment layer 250 may include an electroless nickel immersion gold (ENIG) surface treatment, electroless nickel electroless palladium immersion gold (ENEPIG) surface treatment, and/or electroless palladium immersion gold (EPIG) surface treatment, among other examples.

As further shown in FIG. 2, the semiconductor die package 200 may include a dielectric waveguide structure 252. The dielectric waveguide structure 252 may be included between the semiconductor die 204a and the second semiconductor die 204b. The dielectric waveguide structure 252 is configured for electromagnetic interconnect transmissions between the semiconductor die 204a and the second semiconductor die 204b. The dielectric waveguide structure 252 enables inter-die millimeter wavelength (or less) communication, and thus high-bandwidth communication and/or high-frequency communication (e.g., greater than approximately 10 gigahertz (GHz)), in a WoW/SoIC package. Moreover, the dielectric waveguide structure 252 provides reduced interconnect lengths (and reduced signal propagation times) between the semiconductor die 204a and the second semiconductor die 204b, which supports low-latency applications such as advanced telecommunications (e.g., 5G, 6G, and beyond), flat panel displays, IoT devices, neural networks, cloud computing, data center communications, and/or artificial intelligence, among other examples.

The dielectric waveguide structure 252 is a slab waveguide that includes a plurality of dielectric layers. The dielectric waveguide structure 252 includes a portion of the low-k dielectric layer 238, a portion of the low-k dielectric layer 242, and a high-k dielectric layer 254 between the portion of the low-k dielectric layer 238 and the portion of the low-k dielectric layer 242. In some implementations, the high-k dielectric layer 254 is disposed in, and surrounded by, the low-k dielectric layer 242. In some implementations, the high-k dielectric layer 254 is disposed in, and surrounded by, the low-k dielectric layer 238. The high-k dielectric layer 254 is included on the portion of the low-k dielectric layer 238, and the portion of the low-k dielectric layer 242 is included on the high-k dielectric layer 254.

The dielectric constant of the high-k dielectric layer 254 may be greater relative to a dielectric constant of the low-k dielectric layer 238 and a dielectric constant of the low-k dielectric layer 242 to enable an electromagnetic signal to be loosely confined within the high-k dielectric layer 254 and to achieve total internal reflections of the electromagnetic signal in the high-k dielectric layer 254. As an example, the low-k dielectric layers 238 and 242 may each include a low-k dielectric material, such as a silicon oxide (SiOₓ such as SiO₂), that has a dielectric constant included in a range of approximately 3.9 to approximately 4.2. The high-k dielectric layer 254 may include a high-k dielectric material that has a dielectric constant greater than 4.2 and included in a range of approximately 7 to approximately 1500. However, other values for the ranges of the dielectric constants of the low-k dielectric layers 238 and 242 and the high-k dielectric layer 254 are within the scope of the present disclosure.

Examples of high-k dielectric materials that may be used for the high-k dielectric layer 254 include a strontium titanate (SrTiOₓ such as SrTiO₃ having a dielectric constant of approximately 200), a barium titanate (BaTiOₓ such as BaTiO₃ having a dielectric constant of approximately 500), a barium strontium Titanate (BaSrTiOₓ such as BaSrTiO₃ having a dielectric constant included in a range of approximately 250 to approximately 12000), a lead zirconate titanate (PbZrTiOₓ such as PbZrTiO₃ having a dielectric constant included in a range of approximately 1000 to approximately 1500), a silicon nitride (SiₓN_{y} such as Si₃N₄ having a dielectric constant of approximately 7), a titanium dioxide (TiOₓ such as TiO₂ having a dielectric constant of approximately 83), a zirconium oxide (ZrOₓ such as ZrO₂ having a dielectric constant of approximately 25), an aluminum oxide (AlₓO_{y} such as Al₂O₃ having a dielectric constant of approximately 9), a hafnium oxide (HfOₓ such as HfO₂ having a dielectric constant of approximately 25), a hafnium silicate (HfSiOₓ such as HfSiO₄ having a dielectric constant of approximately 11), a zirconium titanate (ZrTiOₓ such as ZrTiO₄ having a dielectric constant included in a range of approximately 38 to approximately 40), a tantalum oxide (TaₓO_{y} such as Ta₂O₅ having a dielectric constant included in a range of approximately 25 to approximately 110), and/or a yttrium oxide (YₓO_{y} such as Y₂O₃ having a dielectric constant of approximately 15), among other examples. In some implementations, the high-k dielectric layer 254 may include a plurality of high-k dielectric materials that are arranged in a stack structure such as a 1^{st} ZrO₂/Al₂O₃/2^{nd} ZrO₂ stack (ZAZ), a 1^{st} TiO₂/Al₂O₃/2^{nd} TiO₂ stack (TAT), or a 1^{st} ZrO₂/(Ta/Nb) Oₓ-Al₂O₃/2^{nd} ZrO₂ stack (ZTNAZ), among other examples.

The thickness of the high-k dielectric layer 254 may be included in a range of approximately 2.5 microns to approximately 35 microns to achieve a relatively high bandwidth or frequency of electromagnetic signal propagation in the high-k dielectric layer 254. However, other values for the range are within the scope of the present disclosure. The critical angle for total internal reflection in the high-k dielectric layer 254 decreases as the difference in dielectric constant (or refraction index) between the high-k dielectric layer 254 and the low-k dielectric layers 238 and 242 increases. The lesser the critical angle for total internal reflection in the high-k dielectric layer 254, the lesser the thickness of the high-k dielectric layer 254 is needed for high-bandwidth or high-frequency electromagnetic signal propagation in the high-k dielectric layer 254. Accordingly, the thickness of the high-k dielectric layer 254 may be selected based on the dielectric constant of the high-k dielectric material(s) included in the high-k dielectric layer 254. As an example, for a particular operating frequency in the high-k dielectric layer 254, the thickness of the high-k dielectric layer 254 may be approximately 35 microns if the high-k dielectric layer 254 includes a titanium oxide (TiO₂) material, whereas the thickness may be approximately 5 microns if the high-k dielectric layer 254 includes a barium titanate (BaTiO₃) material.

Pairs of conductive structures may be included at opposing ends of the dielectric waveguide structure 252. For example, transceiver conductive structures 256a and 256b may be included on opposing sides of the high-k dielectric layer 254 at a first end of the dielectric waveguide structure 252, and transceiver conductive structures 258a and 258b may be included on opposing sides of the high-k dielectric layer 254 at a second end of the dielectric waveguide structure 252 opposing the first end. The transceiver conductive structures 256a and 256b may be associated with the semiconductor die 204a, and the transceiver conductive structures 258a and 258b may be associated with the semiconductor die 204b. The transceiver conductive structures 256a and 256b and the transceiver conductive structures 258a and 258b may each include conductive structures that are configured to enable propagation of electromagnetic signals (e.g., light) through the dielectric waveguide structure 252. In some implementations, the transceiver conductive structures 256a and 256b include electrode plates that function as an oscillator cavity in between the transceiver conductive structures 256a and 256b, which enables an electrical signal to oscillate between the transceiver conductive structures 256a and 256b to generate a millimeter wave (mmWave) signal. In some implementations, the transceiver conductive structures 258a and 258b include electrode plates that function as an oscillator cavity in between the transceiver conductive structures 258a and 258b that detects the mmWave signal.

In some implementations, the semiconductor die 204a is a transmitter die or a driver die and the semiconductor die 204b is a receiving die or a receiver die. In some other implementations, the semiconductor die 204b is a transmitter die or a driver die and the semiconductor die 204a is a receiving die or a receiver die. In some implementations, the transmitter die includes a transmitter circuit configured to generate an electrical signal. In some implementations, the receiving die includes a receiving circuit configured to receive the electrical signal. In some implementations, the electrical signal generated by the semiconductor die 204a is converted to an electromagnetic signal by circuitry on the semiconductor die 204a and provided to the transceiver conductive structures 256a and 256b, and the electromagnetic signal is transmitted from the semiconductor die 204a through the dielectric waveguide structure 252 to the transceiver conductive structures 258a and 258b. The electromagnetic signal may be received at the transceiver conductive structures 258a and 258b that provides the electromagnetic signal to a transceiver circuit on the semiconductor die 204b that convers the electromagnetic signal back to an electrical signal that is received by the semiconductor die 204b.

The transceiver conductive structures 256a and 258a may each be included in the low-k dielectric layer 238 and below and/or under the high-k dielectric layer 254. The transceiver conductive structures 256a and 258a may be located above and/or over, and may be electrically connected and/or physically connected with respective TDV structures 236. Electrical signals may propagate between the semiconductor die 204a and the transceiver conductive structure 256a through a TDV structure 236. The TDV structure 236 extends between the transceiver conductive structure 256a and the semiconductor die 202 along a side of the semiconductor die 204a or in another location in the semiconductor die package 200. Moreover, electrical signals may propagate between the semiconductor die 204a and the transceiver conductive structure 256a through the semiconductor die 202. For example, the electrical signals may propagate between the semiconductor die 204a and the transceiver conductive structure 256a through one or more conductive pads 232, through one or more via structures 228, and/or through one or more metallization layers 220 of the semiconductor die 202.

Electrical signals may propagate between the semiconductor die 204b and the transceiver conductive structure 258a through a TDV structure 236. The TDV structure 236 extends between the transceiver conductive structure 258a and the semiconductor die 202 along a side of the semiconductor die 204b or in another location in the semiconductor die package 200. Moreover, electrical signals may propagate between the semiconductor die 204b and the transceiver conductive structure 258a through the semiconductor die 202. For example, the electrical signals may propagate between the semiconductor die 204b and the transceiver conductive structure 258a through one or more conductive pads 232, through one or more via structures 228, and/or through one or more metallization layers 220 of the semiconductor die 202.

The transceiver conductive structures 256b and 258b may each be included in the low-k dielectric layer 242 and above and/or over the high-k dielectric layer 254. The transceiver conductive structure 256b may be located above and/or over the transceiver conductive structure 256a, and the transceiver conductive structure 258b may be located above and/or over the transceiver conductive structure 258a. The transceiver conductive structures 256b and 258b may be located below and/or under, and may be electrically connected and/or physically connected with respective connection structures 248. The transceiver conductive structures 256b and 258b may each be electrically connected with an electrical ground through the connection structures 248.

As indicated above, FIG. 2 is provided as an example. Other examples may differ from what is described with regard to FIG. 2.

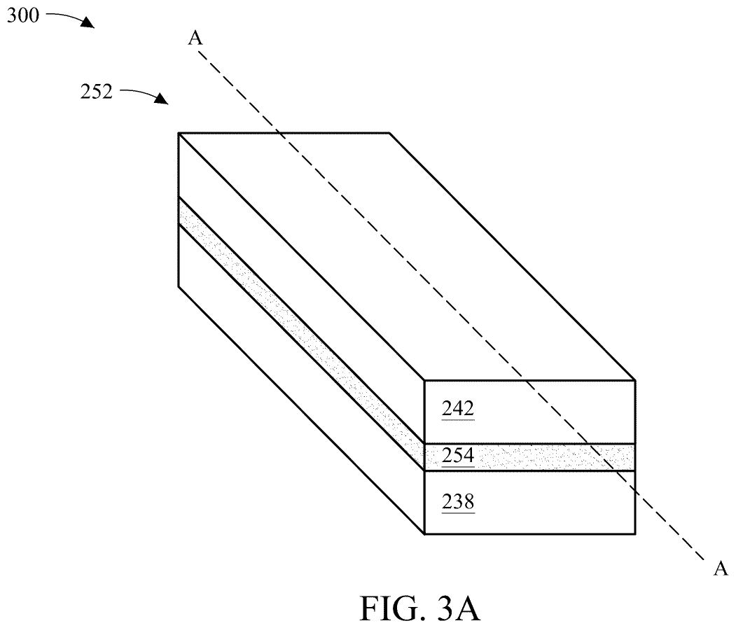

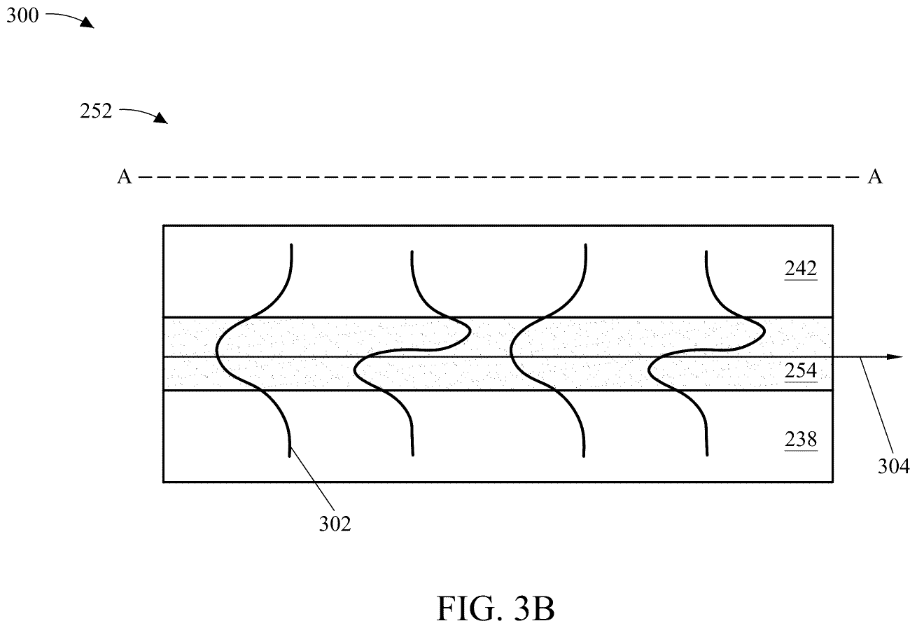

FIGS. 3A and 3B are diagrams of an example implementation 300 of a dielectric waveguide structure 252 described herein. FIG. 3A illustrates a perspective view of the dielectric waveguide structure 252. FIG. 3B illustrates a cross-section view of the dielectric waveguide structure 252 along line A-A in FIG. 3A.

As shown in FIG. 3A, the dielectric waveguide structure 252 may include a low-k dielectric layer 238, a high-k dielectric layer 254 over and/or on the low-k dielectric layer 238, and a low-k dielectric layer 242 over and/or on the high-k dielectric layer 254. The low-k dielectric layer 238, the high-k dielectric layer 254, and the low-k dielectric layer 242 may each include elongated and approximately planar layers along the line A-A. In other words, the thickness of the low-k dielectric layer 238 may be greater relative to a width of the low-k dielectric layer 238 that is approximately perpendicular with the line-A-A. The thickness of the high-k dielectric layer 254 may be greater relative to a width of the high-k dielectric layer 254 that is approximately perpendicular with the line-A-A. The thickness of the low-k dielectric layer 242 may be greater relative to a width of the low-k dielectric layer 242 that is approximately perpendicular with the line-A-A. Accordingly, the dielectric waveguide structure 252 may be referred to as a slab waveguide.

As shown in FIG. 3B, an electromagnetic signal 302 (e.g., light or another type of electromagnetic radiation) may propagate through the dielectric waveguide structure 252 along a propagation direction 304 that is approximately parallel with the low-k dielectric layer 238, the high-k dielectric layer 254, and the low-k dielectric layer 242. The low-k dielectric layers 238 and 242 may correspond to the cladding layers of the dielectric waveguide structure 252, and the high-k dielectric layer 254 may correspond to the core of the dielectric waveguide structure 252. The modes of the electromagnetic signal 302 are loosely confined within the high-k dielectric layer 254), meaning that the modes are primarily contained within the core of the dielectric waveguide structure 252 and are permitted to partially extend into the cladding layers (e.g., the low-k dielectric layers 238 and 242) of the dielectric waveguide structure 252.

The difference in dielectric constants of the high-k dielectric layer 254 and the low-k dielectric layers 238 and 242 enable total internal reflections of the electromagnetic signal 302 to occur within the high-k dielectric layer 254 (e.g., within the core of the dielectric waveguide structure 252). In particular, the dielectric constant of the high-k dielectric layer 254 being greater relative to the dielectric constants of the low-k dielectric layers 238 and 242 provide a relatively low critical angle (e.g., the angle of incidence of the electromagnetic signal 302 at which a total internal reflection of the electromagnetic signal 302 occurs), which increases the likelihood of a total internal reflection of the electromagnetic signal 302 within the high-k dielectric layer 254. A total internal reflection refers to the complete reflection of the electromagnetic signal 302 off of the interface between the high-k dielectric layer 254 and either the low-k dielectric layer 238 or the low-k dielectric layer 242 such that no portion of the electromagnetic signal 302 is refracted into the low-k dielectric layer 238 or the low-k dielectric layer 242.

As an example of the above, a critical angle of approximately 0.2 degrees to approximately 0.3 degrees may be achieved for a high-k dielectric layer 254 that includes lead zirconate titanate (PbZrTiO₃—dielectric constant of approximately 1000 to approximately 1500) and for low-k dielectric layers 238 and 242 that include silicon dioxide (SiO₂—dielectric constant of approximately 3.9). However, other values for the critical angle are within the scope of the present disclosure.

As indicated above, FIGS. 3A and 3B are provided as examples. Other examples may differ from what is described with regard to FIGS. 3A and 3B.

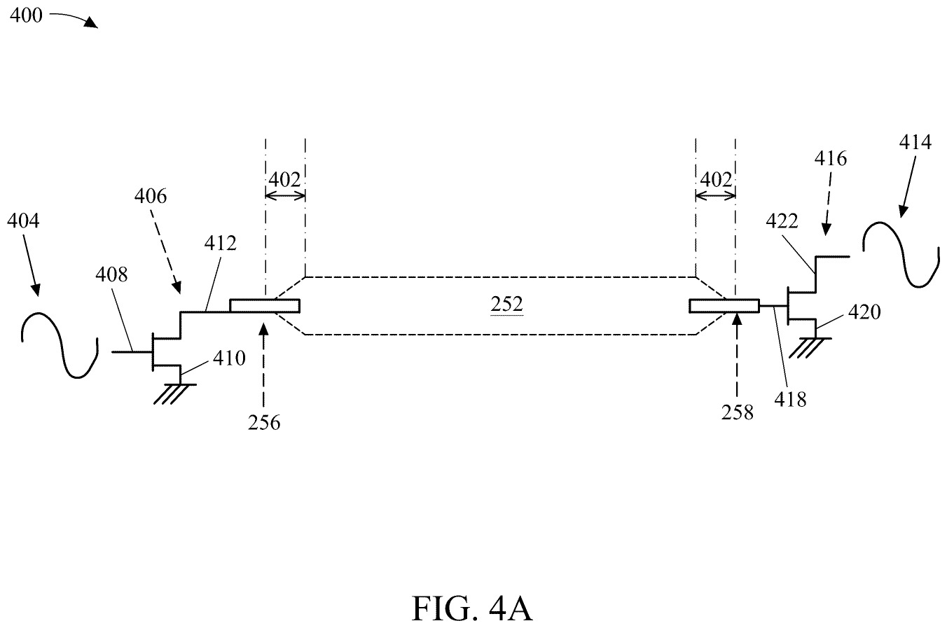

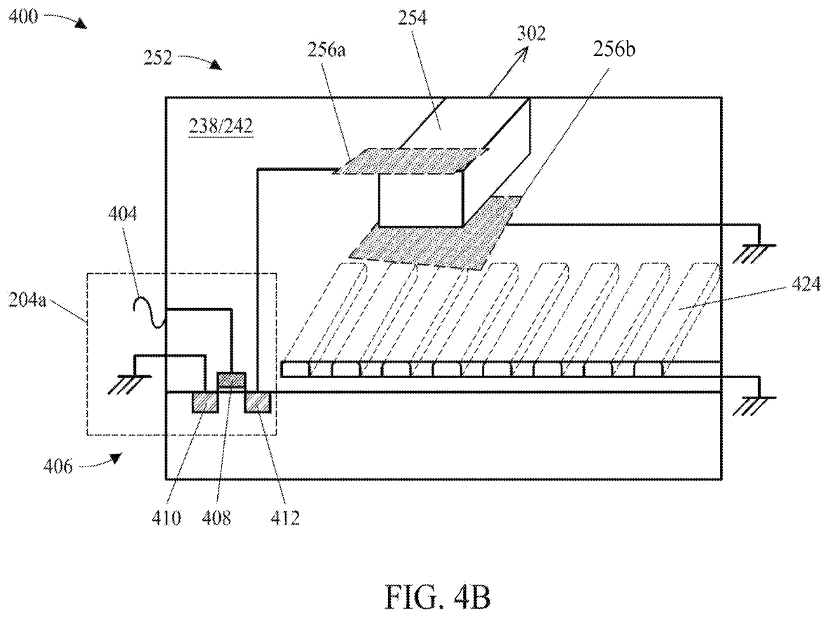

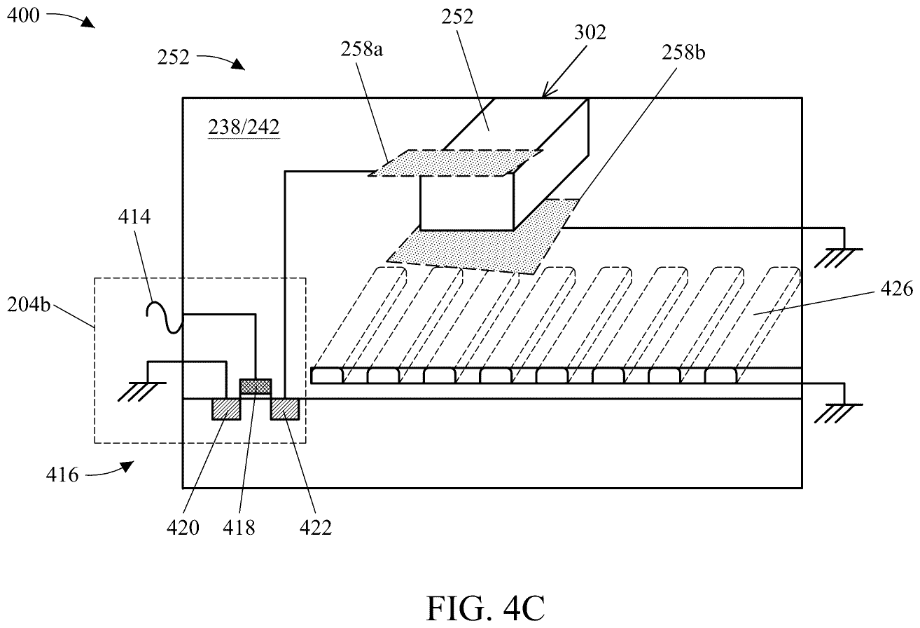

FIGS. 4A-4C are diagrams of an example implementation 400 of a dielectric waveguide structure 252 described herein. FIG. 4A illustrates a top-down view of the dielectric waveguide structure 252. FIGS. 4B and 4C illustrate perspective views of portions of the dielectric waveguide structure 252.

As shown in FIG. 4A, the example implementation 400 includes an example in which the dielectric waveguide structure 252 includes tapered regions 402 at ends of the elongated structure of the dielectric waveguide structure 252. In particular, the dielectric waveguide structure 252 may include a first tapered region 402 at a first end of the dielectric waveguide structure 252 that is coupled with the transceiver conductive structure 256, and a second tapered region 402 at a second end of the dielectric waveguide structure 252 opposing the first end and coupled with the transceiver conductive structure 258. The tapered regions 402 include regions of the dielectric waveguide structure 252 in which a width of the dielectric waveguide structure 252, in a top view of the dielectric waveguide structure 252, decreases toward the first end or toward the second end of the dielectric waveguide structure 252. The tapered regions 402 may function as transition regions that enable an electromagnetic signal 302 in the dielectric waveguide structure 252 to transition between the dielectric waveguide structure 252 and the transceiver conductive structures 256 and 258.

As further shown in FIG. 4A, the transceiver conductive structure 256 may be configured to receive an input signal 404 (e.g., an electromagnetic signal) from a transceiver circuit 406 (e.g., a driver circuit). The input signal 404 may be provided to a gate terminal 408 of the transceiver circuit 406. Source/drain region(s) may refer to a source or a drain, individually or collectively dependent upon the context. A source/drain terminal 410 of the transceiver circuit 406 may be electrically connected to electrical ground, and a source/drain terminal 412 may be electrically connected with the transceiver conductive structure 256. The input signal 404 provided to the gate terminal 408 may be amplified by the transceiver circuit 406 and may be provided to the transceiver conductive structure 256 from the source/drain terminal 412. The transceiver conductive structure 256 initiates propagation of the input signal 404 as an electromagnetic signal 302 that propagates through the dielectric waveguide structure 252 to the transceiver conductive structure 258.

The transceiver conductive structure 258 may be configured to receive the electromagnetic signal 302 from the dielectric waveguide structure 252. The transceiver conductive structure 258 may provide the electromagnetic signal 302 to a transceiver circuit 416 that convers the electromagnetic signal 302 to an output signal 414 (e.g., an electrical signal). The transceiver circuit 416 may be included in the semiconductor die 204b and/or in the semiconductor die 202, among other examples. The transceiver circuit 416 may include a transistor and/or another semiconductor component. The output signal 414 may be provided to a gate terminal 418 of the transceiver circuit 416. A source/drain terminal 420 of the transceiver circuit 416 may be electrically connected to electrical ground. The output signal 414 provided to the gate terminal 418 may be amplified by the transceiver circuit 416 and may be provided to the semiconductor die 204b from a source/drain terminal 422.

FIG. 4B illustrates a portion of the dielectric waveguide structure 252 along with the transceiver conductive structures 256a and 256b, the transceiver circuit 406, and grounding conductive structures 426. As shown in FIG. 4B, the high-k dielectric layer 254 of the dielectric waveguide structure 252 may be surrounded by a plurality of low-k dielectric layers, such as the low-k dielectric layer 238 and the low-k dielectric layer 242. The grounding conductive structures 426 may be electrically connected with the transceiver conductive structure 256b and may correspond to the conductive structures 240, the connection structures 248, and/or other conductive structures in the semiconductor die package 200. The transceiver conductive structure 256a may be electrically connected with the source/drain terminal 412 of the transceiver circuit 406.

The input signal 404 may be provided to the transceiver conductive structure 256a through the source/drain terminal 412 of the transceiver circuit 406. The transceiver conductive structure 256a may convert the input signal 404 to the electromagnetic signal 302, which resonates in the high-k dielectric layer 254 between the transceiver conductive structures 256a and 256b.

The transceiver conductive structures 256a and 256b may each include U-stripline circuits, which are signal transmission line structures that include at least two electric conductors or lines wherein one of the lines forms a ground (also referred to as “ground plane”) (e.g., the transmission line structures 256b) and the other (e.g., the transmission line structures 256a) forms a signal transmission line. The signal transmission line is variously arranged and combined with one or more ground planes or ground lines to form different types of conductive transmission line structures such as microstrips, striplines, and the dielectric waveguide structure 252 serves various RF signal applications.

The transceiver circuit 406 may be included in the semiconductor die 204a. The transceiver circuit 406 may include a frequency synthesizer and based band control module. The input signal 404 may be provided by a terahertz source or another type of source on the semiconductor die 204a. Digital signal blocks may provide an input data stream to signals that are generated by the terahertz source to form the input signal 404. The input signal may be provided to the transceiver conductive structure 256 through a broadband on-chip coupler of the semiconductor die 204a.

FIG. 4C illustrates a portion of the dielectric waveguide structure 252 along with the transceiver conductive structures 258a and 258b, the transceiver circuit 416, and grounding conductive structures 426. As shown in FIG. 4C, the high-k dielectric layer 254 of the dielectric waveguide structure 252 may be surrounded by a plurality of low-k dielectric layers, such as the low-k dielectric layer 238 and the low-k dielectric layer 242. The grounding conductive structures 424 may be electrically connected with the transceiver conductive structure 258b and may correspond to the conductive structures 240, the connection structures 248, and/or other conductive structures in the semiconductor die package 200. The transceiver conductive structure 258a may be electrically connected with the gate terminal 418 of the transceiver circuit 416.

The electromagnetic signal 302 may be provided to the transceiver conductive structure 258a, which converts the electromagnetic signal 302 to the output signal 414. The output signal 414 is provided to the gate terminal 418 of the transceiver circuit 416.

The transceiver conductive structures 258a and 258b may each include U-stripline circuits, which are signal transmission line structures that include at least two electric conductors or lines wherein one of the lines forms a ground (also referred to as “ground plane”) (e.g., the transmission line structures 258b) and the other (e.g., the transmission line structures 258a) forms a signal transmission line. The signal transmission line is variously arranged and combined with one or more ground planes or ground lines to form different types of conductive transmission line structures such as microstrips, striplines, and the dielectric waveguide structure 252 serves various RF signal applications.

The transceiver circuit 416 may be included in the semiconductor die 204b. The electromagnetic signal 302 may be provided to a broadband on-chip coupler of the semiconductor die 204b to the transceiver circuit 416, which includes a frequency synthesizer and baseband control module that controls conversion of the electromagnetic signal 302 to the output signal 414. Digital signal blocks may extract the output data stream (corresponding to the output signal 414) from the electromagnetic signal 302 that is then provided to a terahertz source of the transceiver circuit 416.

As indicated above, FIGS. 4A-4C are provided as examples. Other examples may differ from what is described with regard to FIGS. 4A-4C.

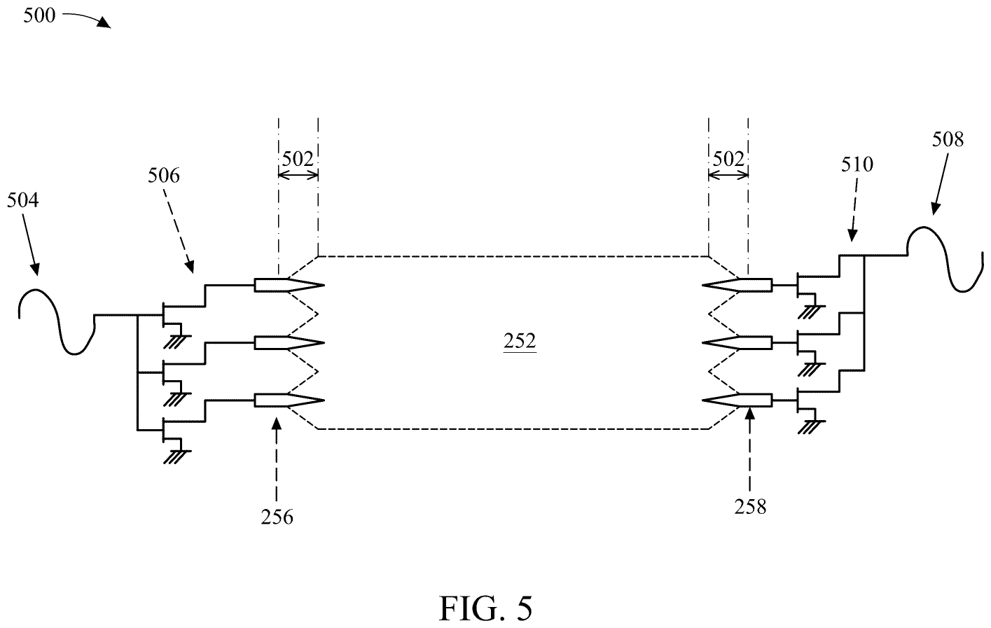

FIG. 5 is a diagram of an example implementation 500 of a dielectric waveguide structure 252 described herein. FIG. 5 illustrates a top-down view of the dielectric waveguide structure 252.

As shown in FIG. 5, the example implementation 500 includes an example in which the dielectric waveguide structure 252 includes respective pluralities of tapered regions 502 at opposing ends of the elongated structure of the dielectric waveguide structure 252. In particular, the dielectric waveguide structure 252 may include a first plurality of tapered regions 502 at a first end of the dielectric waveguide structure 252 that is coupled with a plurality of transceiver conductive structures 256, and a second plurality of tapered regions 502 at a second end of the dielectric waveguide structure 252 opposing the first end and coupled with a plurality of transceiver conductive structures 258. In some implementations, each transceiver conductive structure 256 is coupled with a respective tapered region 502 of the first plurality of tapered regions 502, and each transceiver conductive structure 258 is coupled with a respective tapered region 502 of the second plurality of tapered regions 502.

As further shown in FIG. 5, an input signal 504 may be provided to a plurality of transceiver circuits 506. Each of the plurality of transceiver conductive structures 256 may be electrically connected with a respective transceiver circuit of the plurality of transceiver circuits 506. The input signal 504 may be amplified by the plurality of transceiver circuits 506 and converted to a plurality of electromagnetic signals 302 by the plurality of transceiver conductive structures 256. The plurality of electromagnetic signals 302 may propagate through the dielectric waveguide structure 252 to the plurality of transceiver conductive structures 258. The plurality of transceiver conductive structures 258 may convert the plurality of electromagnetic signals 302 to a plurality of output signals 508 that are provided to a plurality of transceiver circuits 510. Each of the plurality of transceiver conductive structures 258 may be electrically connected with a respective transceiver circuit of the plurality of transceiver circuits 510.

The plurality of tapered regions 502, the plurality of transceiver circuits 506, and the plurality of transceiver circuits 510 may enable the electromagnetic signals 302 to be tuned for specific operating frequencies and/or for specific modes, which may increase the efficiency and signal quality of the electromagnetic signals 302.

As indicated above, FIG. 5 is provided as an example. Other examples may differ from what is described with regard to FIG. 5.

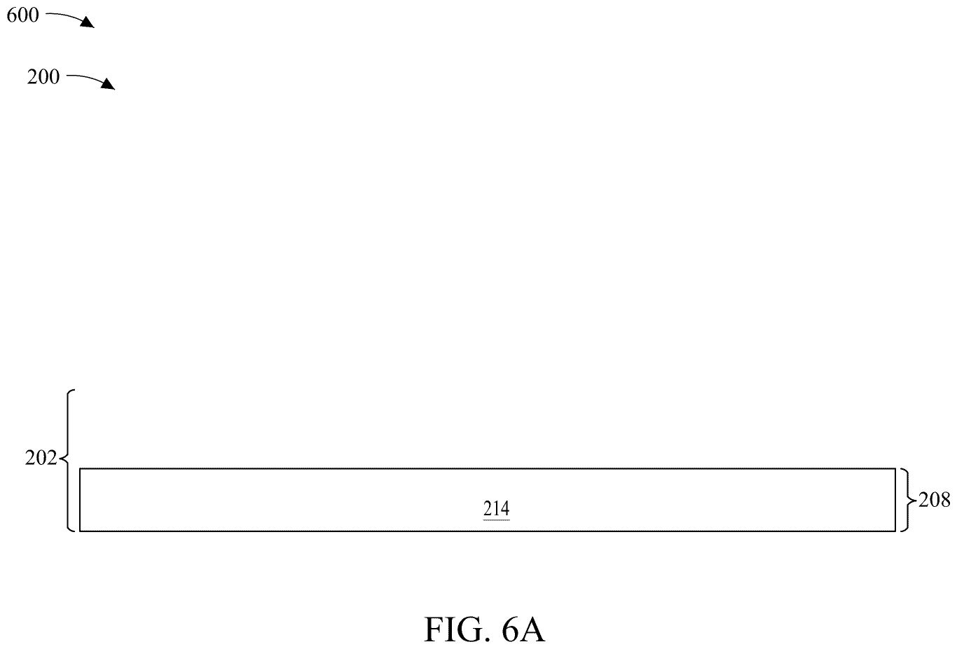

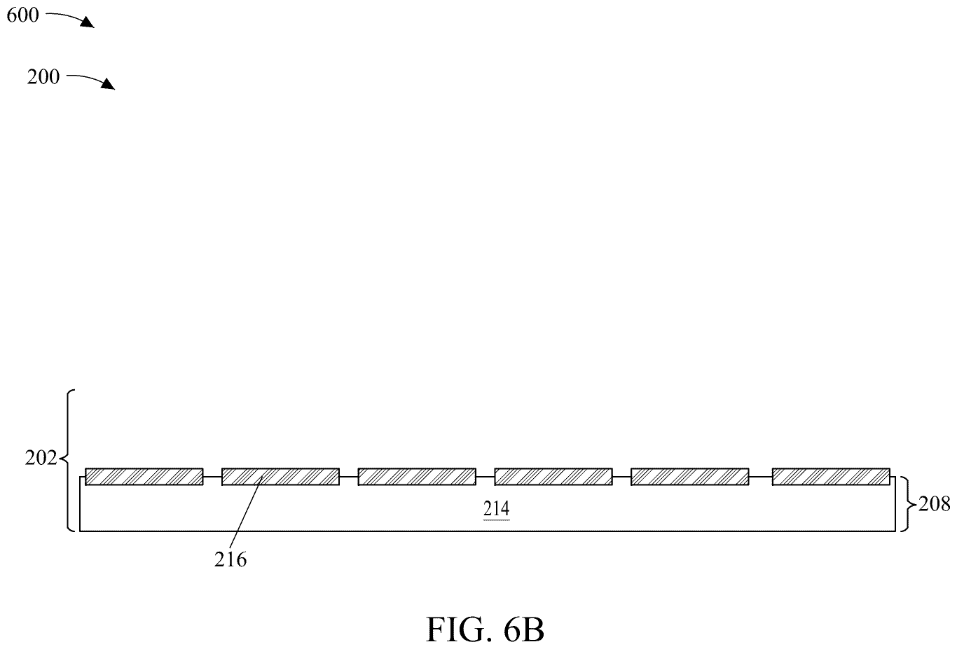

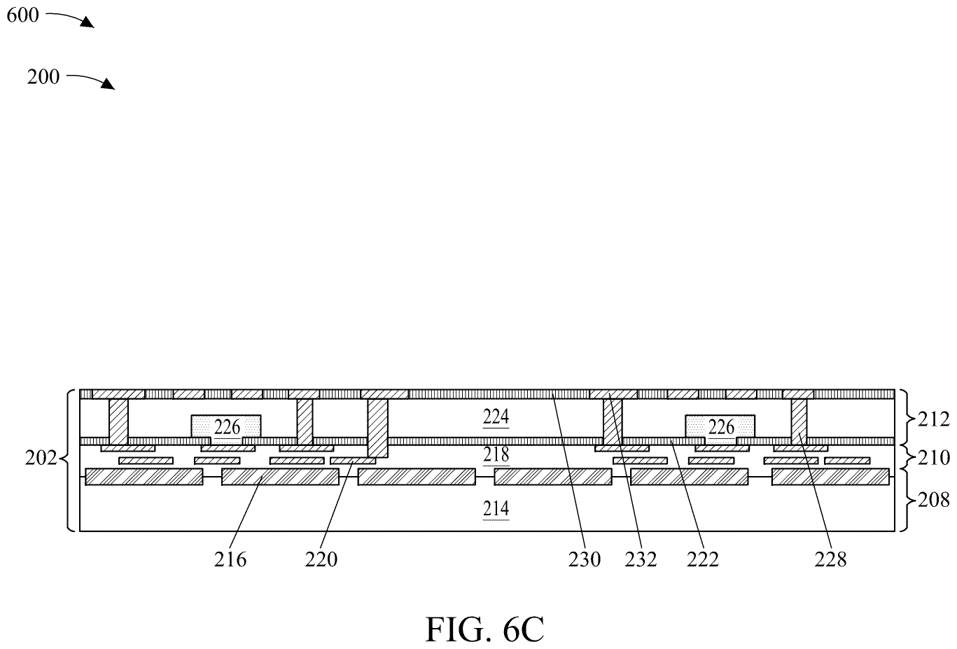

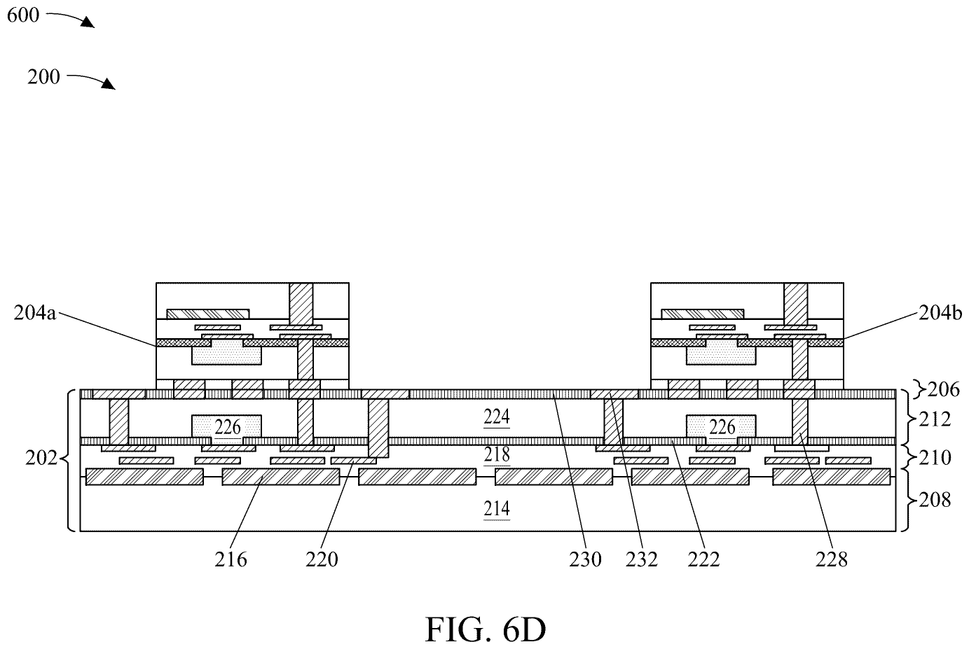

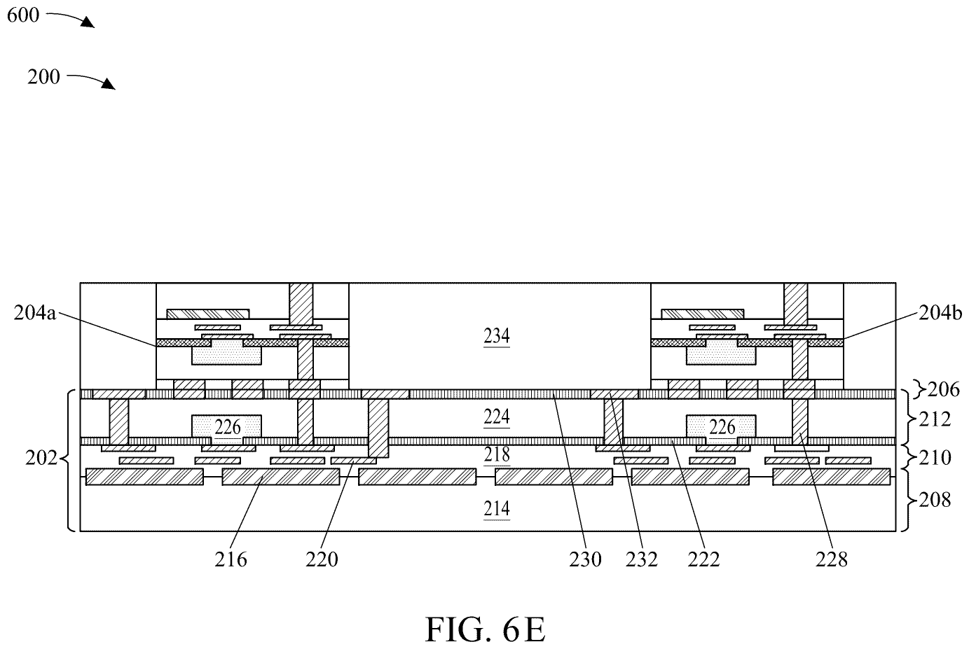

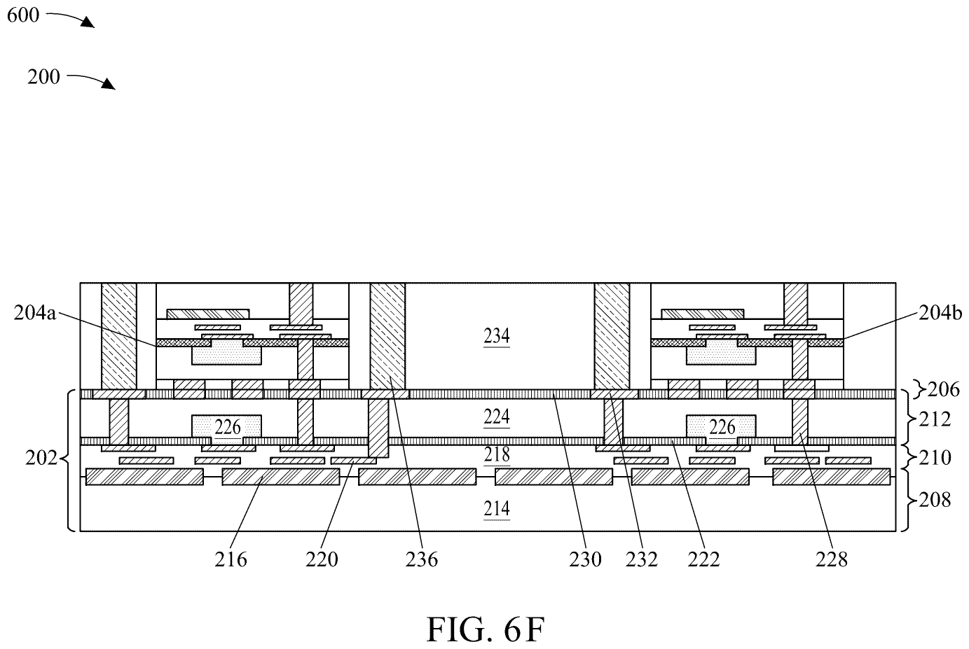

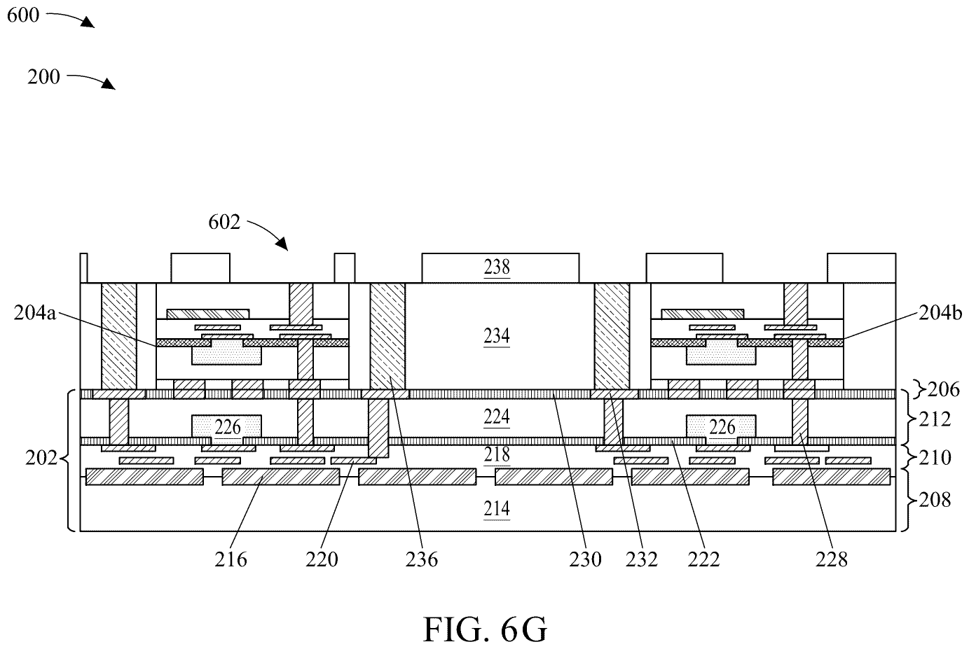

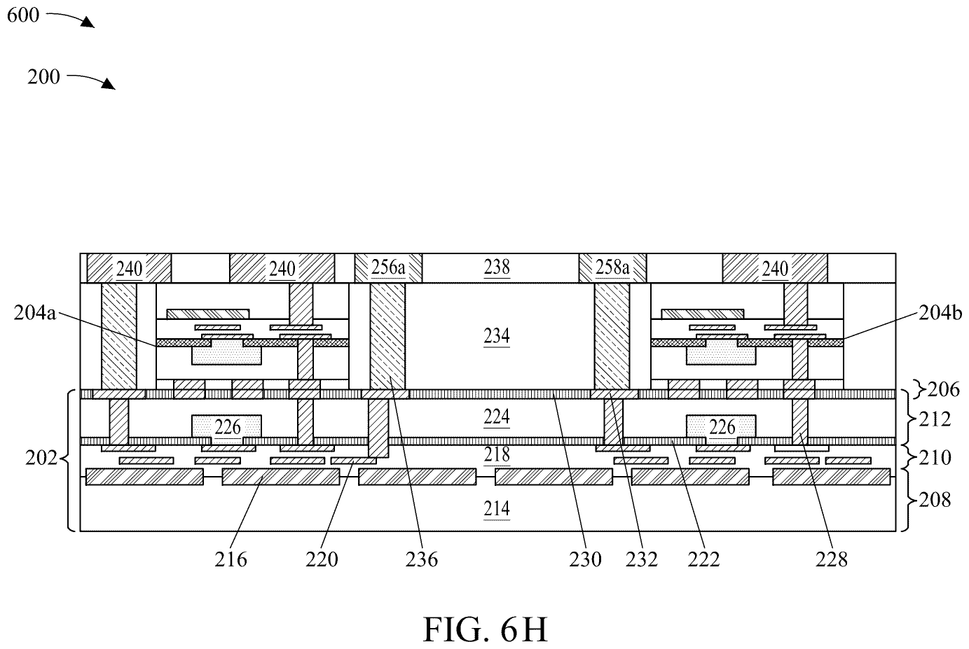

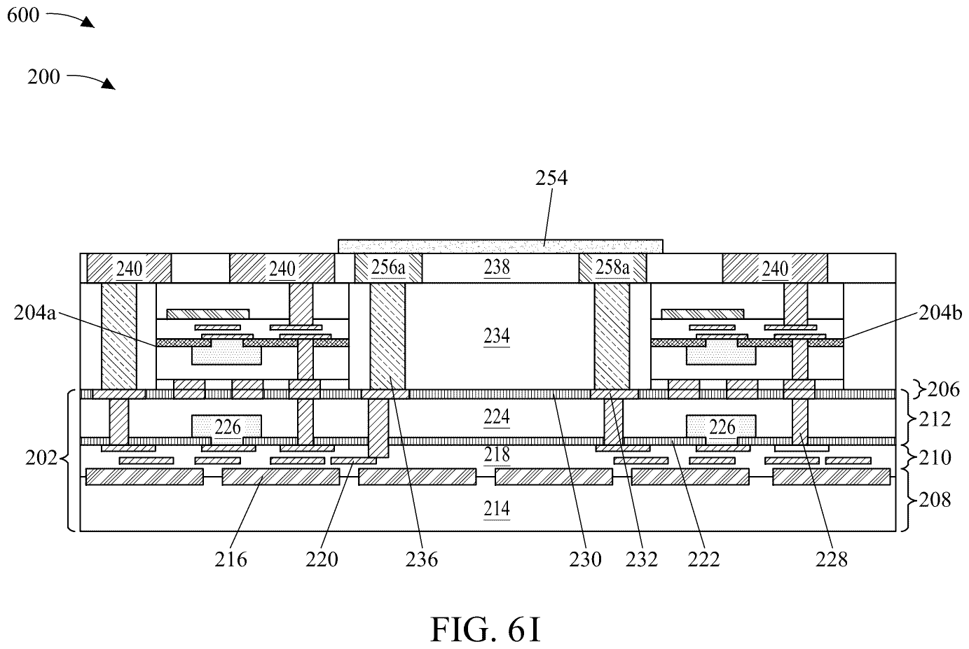

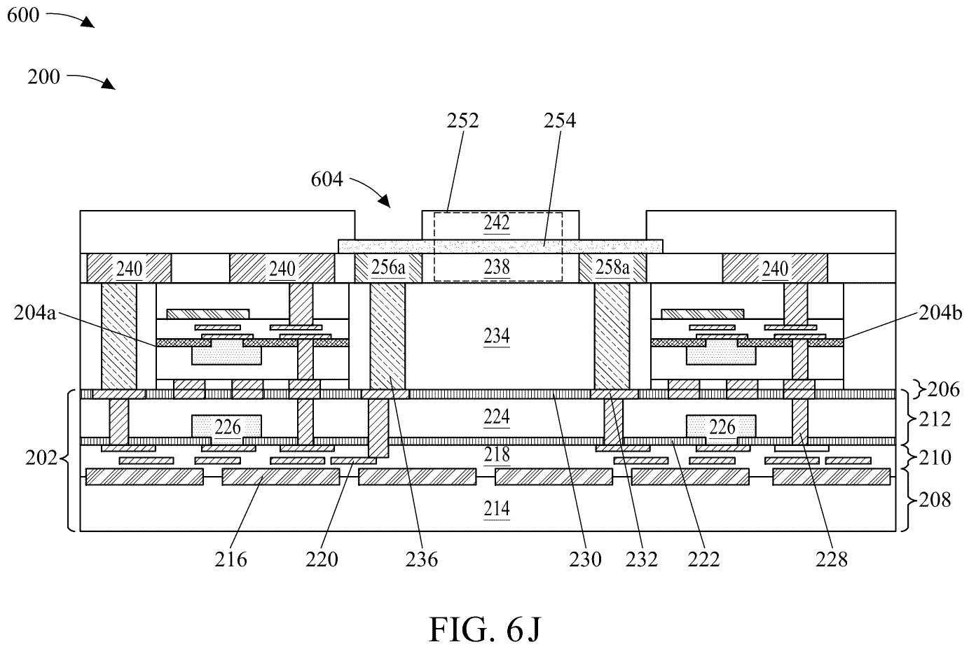

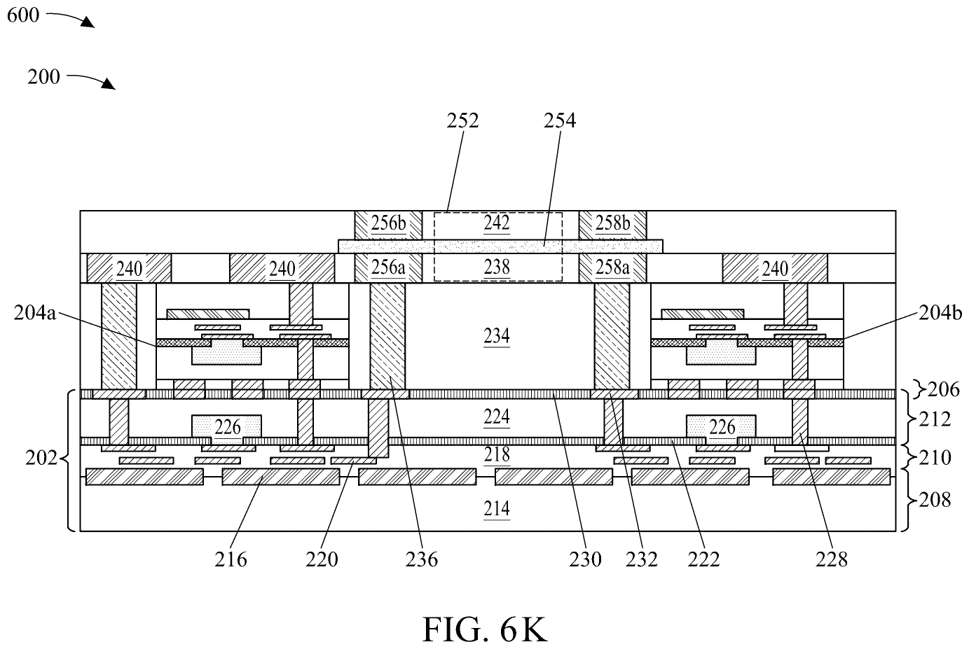

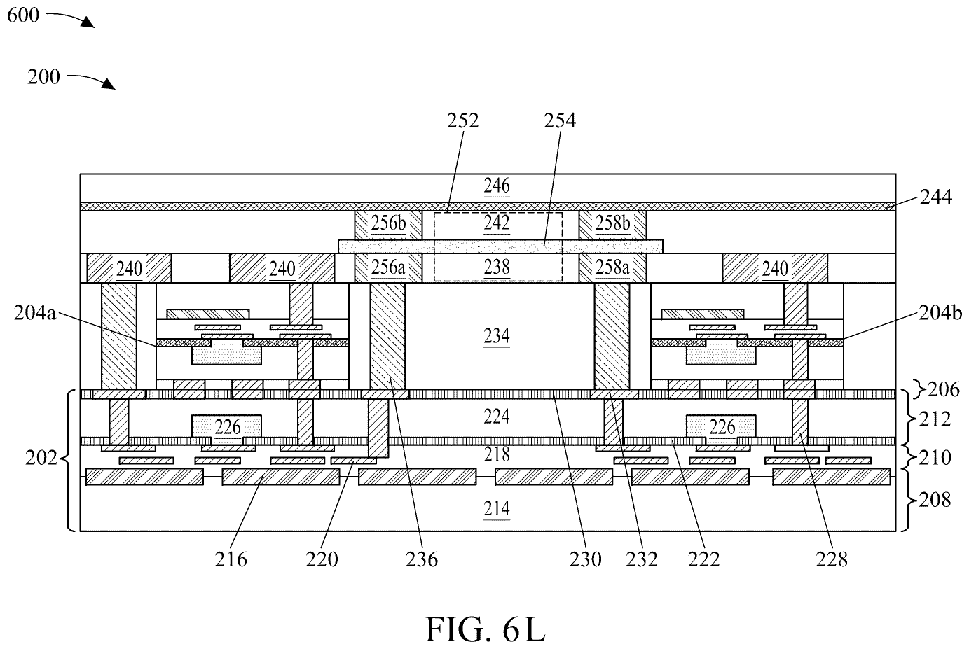

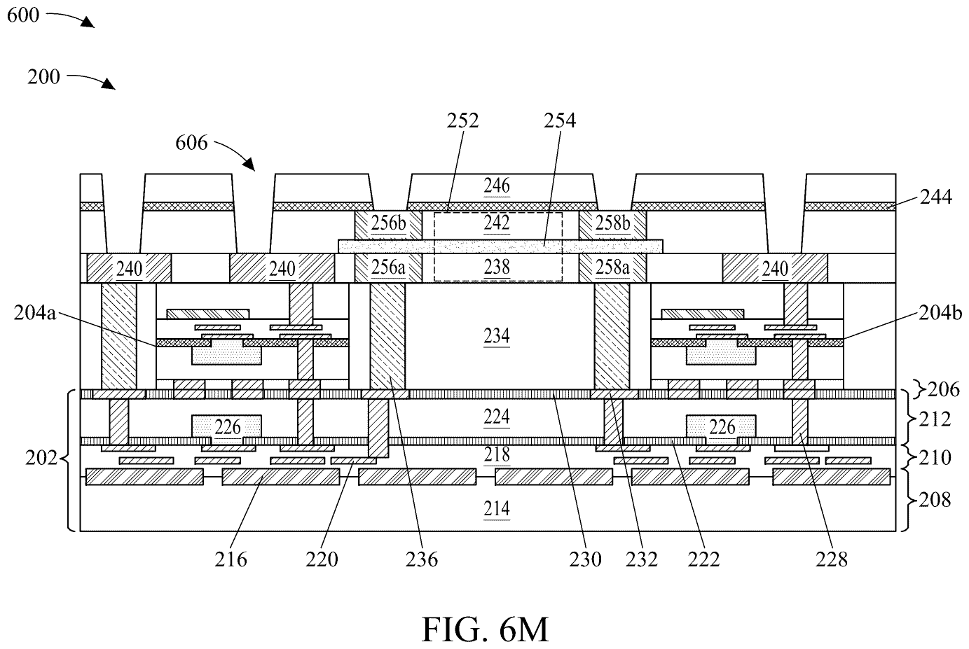

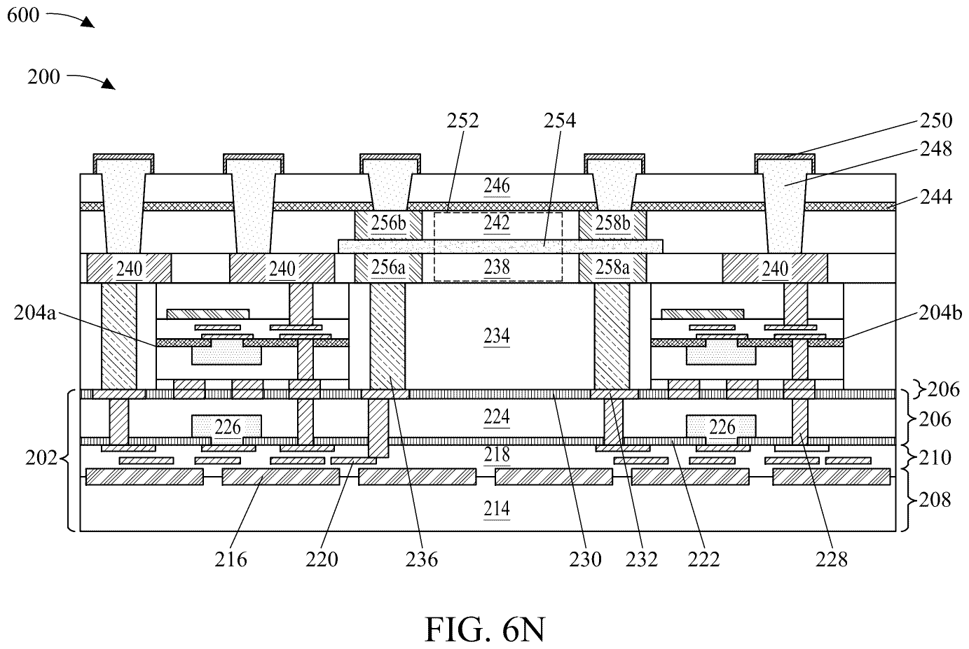

FIGS. 6A-6N are diagrams of an example implementation 600 of forming a portion of a semiconductor die package 200 described herein. In some implementations, one or more operations described in connection with FIGS. 6A-6N may be performed by one or more of the semiconductor processing tools 102-114 and/or the wafer/die transport tool 116. In some implementations, one or more operations described in connection with FIGS. 6A-6N may be performed by another semiconductor processing tool.

Turning to FIG. 6A, one or more of the operations in the example implementation 600 may be performed in connection with the substrate 214 of the device region 208 of the semiconductor die 202. The substrate 214 of the device region 208 may be provided in the form of a semiconductor wafer or another type of substrate.

As shown in FIG. 6B, one or more semiconductor devices 216 may be formed in and/or on the substrate 214 of the device region 208. For example, one or more of the semiconductor processing tools 102-114 may perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor devices of another type. In some implementations, one or more regions of the substrate 214 of the device region 208 may be doped in an ion implantation operation to form one or more p-wells, one or more n-wells, and/or one or more deep n-wells. In some implementations, the deposition tool 102 may deposit one or more source/drain regions, one or more gate structures, and/or one or more shallow trench isolation (STI) regions, among other examples.

As shown in FIG. 6C, the redistribution region 210 of the semiconductor die 202 may be formed over and/or on the device region 208. The interconnect region 212 may be formed over and/or on the redistribution region 210. One or more of the semiconductor processing tools 102-114 may form the redistribution region 210 by forming one or more dielectric layers 218 and forming a plurality of metallization layers 220 in the plurality of dielectric layers 218. For example, the deposition tool 102 may deposit a first layer of the one or more dielectric layers 218 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 220 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 216. The deposition tool 102, the etch tool 108, the plating tool 112, and/or another semiconductor processing tool may continue to perform similar processing operations to forming the redistribution region 210 until a sufficient or desired arrangement of metallization layers 220 is achieved.

As further shown in FIG. 6C, one or more of the semiconductor processing tools 102-114 may form a dielectric layer 222 of the interconnect region 212 over and/or on the redistribution region 210. The deposition tool 102 may deposit the dielectric layer 222 using a CVD technique, an ALD technique, a PVD technique, and/or another type of deposition technique. The etch tool 108 may remove portions of the dielectric layer 222 to form recesses in the dielectric layer 222 to expose one or more of the metallization layers 220 through the recesses. The deposition tool 102 and/or the plating tool 112 may form conductive pads 226 in the recesses using a CVD technique, an ALD technique, a PVD technique, an electroplating technique, and/or another type of deposition technique. The conductive pads 226 may be electrically connected and/or physical connected with the one or more metallization layers 220.

As further shown in FIG. 6C, one or more of the semiconductor processing tools 102-114 may form a dielectric layer 224 of the interconnect region 212 over and/or on the dielectric layer 222. The deposition tool 102 may deposit the dielectric layer 224 using a CVD technique, an ALD technique, a PVD technique, and/or another type of deposition technique. The etch tool 108 may remove portions of the dielectric layer 224 and portions of the dielectric layer 224 to form recesses in the dielectric layer 222 and the dielectric layer 224 to expose one or more of the metallization layers 220 through the recesses. The deposition tool 102 and/or the plating tool 112 may form via structures 228 in the recesses using a CVD technique, an ALD technique, a PVD technique, an electroplating technique, and/or another type of deposition technique. The via structures 228 may be electrically connected and/or physical connected with the one or more metallization layers 220.

As further shown in FIG. 6C, one or more of the semiconductor processing tools 102-114 may form a dielectric layer 230 of the interconnect region 212 over and/or on the dielectric layer 224. The deposition tool 102 may deposit the dielectric layer 230 using a CVD technique, an ALD technique, a PVD technique, and/or another type of deposition technique. The etch tool 108 may remove portions of the dielectric layer 230 to form recesses in the dielectric layer 230. One or more of the recesses may be formed over one or more of the via structures 228 to expose the one or more via structures 228 through the recesses. The deposition tool 102 and/or the plating tool 112 may form conductive pads 232 in the recesses using a CVD technique, an ALD technique, a PVD technique, an electroplating technique, and/or another type of deposition technique. One or more of the conductive pads 232 may be electrically connected and/or physical connected with one or more of the via structures 228.

As shown in FIG. 6D, a semiconductor die 204a may be bonded with the semiconductor die 202 at a bonding interface 206 such that the semiconductor die 204a and the semiconductor die 202 are vertically arranged or stacked in a WoW configuration. The bonding tool 114 may perform a bonding operation to bond the semiconductor die 204a and the semiconductor die 202 at the bonding interface 206. The bonding operation may include a direct bonding operation (or hybrid bonding operation) in which bonding of the semiconductor die 204a and the semiconductor die 202 is achieved through the physical connection of the conductive pads 232 with the contacts on the semiconductor die 204a.

As further shown in FIG. 6D, a semiconductor die 204b may be bonded with the semiconductor die 202 at the bonding interface 206 such that the semiconductor die 204b and the semiconductor die 202 are vertically arranged or stacked in a WoW configuration. The semiconductor die 204a and the semiconductor die 204b may be bonded to the same side of the semiconductor die 202 such that the semiconductor die 204a and the semiconductor die 204b are side by side or horizontally arranged above the semiconductor die 202 in the semiconductor die package 200. The bonding tool 114 may perform a bonding operation to bond the semiconductor die 204b and the semiconductor die 202 at the bonding interface 206. The bonding operation may include a direct bonding operation (or hybrid bonding operation) in which bonding of the semiconductor die 204b and the semiconductor die 202 is achieved through the physical connection of the conductive pads 232 with the contacts on the semiconductor die 204b.

As shown in FIG. 6E, a dielectric fill layer 234 may be formed over and/or on the semiconductor die 202. The dielectric fill layer 234 may fill in gaps between the semiconductor die 204a and the semiconductor die 204b such that the dielectric fill layer 234 surrounds the semiconductor die 204a and the semiconductor die 204b. The deposition tool 102 may deposit the dielectric fill layer 234 using a CVD technique, a PVD technique, an ALD technique, another deposition technique described above in connection with FIG. 1, and/or a deposition technique other than as described above in connection with FIG. 1. In some implementations, the dielectric fill layer 234 is deposited such that excess material of the dielectric fill layer 234 covers the top surfaces of the semiconductor die 204a and the semiconductor die 204b. This ensures that the gaps between the semiconductor die 204a and the semiconductor die 204b are fully filled and are substantially void free. In these implementations, the planarization tool 110 may perform a CMP operation to planarize the dielectric fill layer 234 after the dielectric fill layer 234 is deposited to expose the top surfaces of the semiconductor die 204a and the semiconductor die 204b, and such that the top surfaces of the semiconductor die 204a, the semiconductor die 204b, and the dielectric fill layer 234 are approximately coplanar.

As shown in FIG. 6F, TDV structures 236 may be formed in and through the dielectric fill layer 234. One or more of the TDV structures 236 may extend along sides of the semiconductor die 204a and/or along sides of the semiconductor die 204b. The etch tool 108 may remove portions of the dielectric fill layer 234 to form recesses in the dielectric fill layer 234 to expose one or more of the conductive pads 232 through the recesses. The deposition tool 102 and/or the plating tool 112 may deposit the TDV structures 236 in the recesses using a CVD technique, an ALD technique, a PVD technique, an electroplating technique, and/or another type of deposition technique. The TDV structures 236 may be electrically connected and/or physical connected with the one or more conductive pads 232.

As shown in FIG. 6G, the low-k dielectric layer 238 may be formed over and/or on the semiconductor die 204a, over and/or on the semiconductor die 204b, over and/or on the dielectric fill layer 234, and/or over and/or on the TDV structures 236. The deposition tool 102 may deposit the low-k dielectric layer 238 using a CVD technique, a PVD technique, an ALD technique, another deposition technique described above in connection with FIG. 1, and/or a deposition technique other than as described above in connection with FIG. 1. In some implementations, the deposition tool 102 deposits the low-k dielectric material of the low-k dielectric layer 238 at room temperature or another low temperature. The deposition tool 102 may deposit the low-k dielectric material in liquid form (e.g., in a liquid phase of the low-k dielectric material) and may perform a low-temperature (e.g., less than approximately 200 degrees Celsius or another suitable temperature) cure to cause the low-k dielectric material to solidify and harden. In some implementations, the planarization tool 110 may perform a CMP operation to planarize the low-k dielectric layer 238 after the low-k dielectric layer 238 is formed.

As further shown in FIG. 6G, recesses 602 may be formed in the low-k dielectric layer 238. In some implementations, the recesses 602 are formed over one or more of the TDV structures 236 to expose the tops of the TDV structures 236 through the recesses 602. In some implementations, the recesses 602 are formed over the semiconductor die 204a and/or over the semiconductor die 204b.

In some implementations, a pattern in a photoresist layer is used to form the recesses 602. In these implementations, the deposition tool 102 forms the photoresist layer over the low-k dielectric layer 238. The exposure tool 104 exposes the photoresist layer to a radiation source to pattern the photoresist layer. The developer tool 106 develops and removes portions of the photoresist layer to expose the pattern. The etch tool 108 etches through the low-k dielectric layer 238 to form the recesses 602. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 602 based on a pattern.

As shown in FIG. 6H, conductive structures 240, a transceiver conductive structure 256a, and a transceiver conductive structure 258a may be formed in the recesses 602. The deposition tool 102 and/or the plating tool 112 may deposit the conductive structures 240, the transceiver conductive structure 256a, and the transceiver conductive structure 258a using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the conductive structures 240, the transceiver conductive structure 256a, and/or the transceiver conductive structure 258a after the conductive structures 240, the transceiver conductive structure 256a, and/or the transceiver conductive structure 258a are deposited.

As shown in FIG. 6I, a high-k dielectric layer 254 may be formed over and/or on the low-k dielectric layer 238, over and/or on the transceiver conductive structure 256a, and/or over and/or on the transceiver conductive structure 258a. The deposition tool 102 may deposit the high-k dielectric layer 254 as a blanket layer that covers the semiconductor die package 200, and the etch tool 108 may etch the high-k dielectric layer 254 to remove portions of the high-k dielectric layer 254. The etch tool 108 may etch the high-k dielectric layer 254 to remove the portions of the high-k dielectric layer 254 over the semiconductor die 204a and the semiconductor die 204b. The remaining portion of the high-k dielectric layer 254 may be located between the semiconductor die 204a and the semiconductor die 204b.

The deposition tool 102 may use various deposition techniques to deposit the high-k dielectric layer 254 to achieve a particular dielectric constant for the high-k dielectric layer 254 and/to achieve a particular thickness for the high-k dielectric layer 254, among other examples. In some implementations, the deposition tool 102 may form the high-k dielectric layer 254 using a low temperature CVD technique. Here, the temperature at which the deposition tool 102 deposits the material of the high-k dielectric layer 254 may be between room temperature and approximately 220 degrees Celsius.

As an example, the deposition tool 102 may perform a plasma enhanced CVD (PECVD) operation, a sub-atmospheric CVD (SACVD) operation, a laser CVD (LCVD) operation, an atmospheric pressure CVD (APCVD) operation, a metal organic CVD (MOCVD) operation, and/or another type of CVD operation at a temperature that is included in a range of approximately 150 degrees Celsius to approximately 200 degrees Celsius to deposit a silicon nitride (SiₓN_{y}) material or a silicon oxygen nitride (SiOₓN_{y}) material to achieve a dielectric constant that is included in a range of approximately 6.9 to approximately 7 for the high-k dielectric layer 254. However, other values for these ranges are within the scope of the present disclosure.

As another example, the deposition tool 102 may perform a laser CVD (LCVD) operation and/or another type of CVD operation at a temperature that is less than approximately 220 degrees Celsius to deposit a titanium oxide (TiOₓ such as TiO₂) material to achieve a dielectric constant that is included in a range of approximately 80 to approximately 100 for the high-k dielectric layer 254. However, other values for these ranges are within the scope of the present disclosure.

As another example, the deposition tool 102 may perform a CVD operation at a temperature that is included in arrange of approximately 200 degrees Celsius to approximately 220 degrees Celsius to deposit a ZAZ stack, a titanium oxide (TiOₓ such as TiO₂) material, a zirconium dioxide (ZrOₓ) material, an aluminum oxide (AlₓO_{y}) material, a hafnium oxide (HfOₓ) material, a hafnium silicate (HfSiOₓ) material, a zirconium titanate (ZrTiOₓ) material, and/or a tantalum oxide (TaOₓ) material for the high-k dielectric layer 254.

As another example, the deposition tool 102 may perform a laser CVD (LCVD) operation and/or another type of CVD operation at a temperature that is less than approximately 200 degrees Celsius to deposit a strontium titanate (SrTiOₓ) material, a barium titanate (BaTiOₓ) material, a barium strontium Titanate (BaSrTiOₓ), a lead zirconate titanate (PbZrTiOₓ) material, and/or another material for the high-k dielectric layer 254.

As another example, the deposition tool 102 may deposit a silicon nitride (SiₓN_{y}) material for the high-k dielectric layer 254 at room temperature (e.g., approximately 25 degrees Celsius) or another low temperature. The deposition tool 102 may deposit the silicon nitride material in liquid form (e.g., in a liquid phase of the silicon nitride material) and may perform a low-temperature (e.g., less than approximately 250 degrees Celsius or another suitable temperature) cure to remove solvents from the silicon nitride material and to cause the silicon nitride material to solidify and harden.

As another example, the deposition tool 102 may deposit a polymer material at room temperature (e.g., approximately 25 degrees Celsius) or another low temperature. The polymer material may include polybenzoxazole (PBO), a polyimide, a low temperature polyimide (LTPI), an epoxy resin, an acrylic resin, a phenol resin, and/or benzocyclobutene (BCB), among other examples. The deposition tool 102 may deposit the polymer material in liquid form (e.g., in a liquid phase of the polymer material) and may perform a low-temperature (e.g., less than approximately 250 degrees Celsius or another suitable temperature) cure to remove solvents from the polymer material and to cause the polymer material to solidify and harden.

As shown in FIG. 6J, the low-k dielectric layer 242 may be formed over and/or on the low-k dielectric layer 238 and/or over and/or on the high-k dielectric layer 254 such that the low-k dielectric layer 242 surrounds the high-k dielectric layer 254. The deposition tool 102 may deposit the low-k dielectric layer 242 using a CVD technique, a PVD technique, an ALD technique, another deposition technique described above in connection with FIG. 1, and/or a deposition technique other than as described above in connection with FIG. 1. In some implementations, the deposition tool 102 deposits the low-k dielectric material of the low-k dielectric layer 242 at room temperature or another low temperature. The deposition tool 102 may deposit the low-k dielectric material in liquid form (e.g., in a liquid phase of the low-k dielectric material) and may perform a low-temperature (e.g., less than approximately 200 degrees Celsius or another suitable temperature) cure to cause the low-k dielectric material to solidify and harden. In some implementations, the planarization tool 110 may perform a CMP operation to planarize the low-k dielectric layer 242 after the low-k dielectric layer 242 is formed.

As further shown in FIG. 6J, recesses 604 may be formed in the low-k dielectric layer 242. In some implementations, the recesses 604 are formed over opposing ends of the high-k dielectric layer 254. The opposing ends may be located above and/or over the transceiver conductive structure 256a and the transceiver conductive structure 258a.

In some implementations, a pattern in a photoresist layer is used to form the recesses 604. In these implementations, the deposition tool 102 forms the photoresist layer over the low-k dielectric layer 242. The exposure tool 104 exposes the photoresist layer to a radiation source to pattern the photoresist layer. The developer tool 106 develops and removes portions of the photoresist layer to expose the pattern. The etch tool 108 etches through the low-k dielectric layer 242 to form the recesses 604. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 604 based on a pattern.

As shown in FIG. 6K, a transceiver conductive structure 256b and a transceiver conductive structure 258b may be formed in the recesses 604. The deposition tool 102 and/or the plating tool 112 may deposit the transceiver conductive structure 256b and the transceiver conductive structure 258b using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the transceiver conductive structure 256b and/or the transceiver conductive structure 258b after the transceiver conductive structure 256b and/or the transceiver conductive structure 258b are deposited.

As shown in FIG. 6L, a passivation layer 244 may be formed over and/or on the low-k dielectric layer 242, over and/or on the transceiver conductive structure 256b, and/or over and/or on the transceiver conductive structure 258b. Another passivation layer 246 may be formed over and/or on the passivation layer 244. The deposition tool 102 may deposit the passivation layer 244 and/or the passivation layer 246 using a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the passivation layer 244 and/or the passivation layer 246 after the passivation layer 244 and/or the passivation layer 246 are formed.

As further shown in FIG. 6M, recesses 606 may be formed through passivation layer 246, through the passivation layer 244, and/or through the low-k dielectric layer 242. In some implementations, one or more recesses 606 are formed over one or more conductive structures 240 to expose the conductive structures 240 through the one or more recesses 606. In some implementations, a recess 606 is formed over the transceiver conductive structure 256b to expose the transceiver conductive structure 256b through the recess 606. In some implementations, a recess 606 is formed over the transceiver conductive structure 258b to expose the transceiver conductive structure 258b through the recess 606.

In some implementations, a pattern in a photoresist layer is used to form the recesses 606. In these implementations, the deposition tool 102 forms the photoresist layer over the passivation layer 246. The exposure tool 104 exposes the photoresist layer to a radiation source to pattern the photoresist layer. The developer tool 106 develops and removes portions of the photoresist layer to expose the pattern. The etch tool 108 etches through passivation layer 246, through the passivation layer 244, and/or through the low-k dielectric layer 242 to form the recesses 606. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 606 based on a pattern.

As shown in FIG. 6N, connection structures 248 may be formed in the recesses 606. The deposition tool 102 and/or the plating tool 112 may deposit the connection structures 248 using a CVD technique, a PVD technique, an ALD technique, an electroplating technique, another deposition technique described above in connection with FIG. 1, and/or a deposition technique other than as described above in connection with FIG. 1. The deposition tool 102 and/or the plating tool 112 may also deposit the treatment layer 250 on the connection structures 248.

As indicated above, FIGS. 6A-6N are provided as an example. Other examples may differ from what is described with regard to FIGS. 6A-6N.

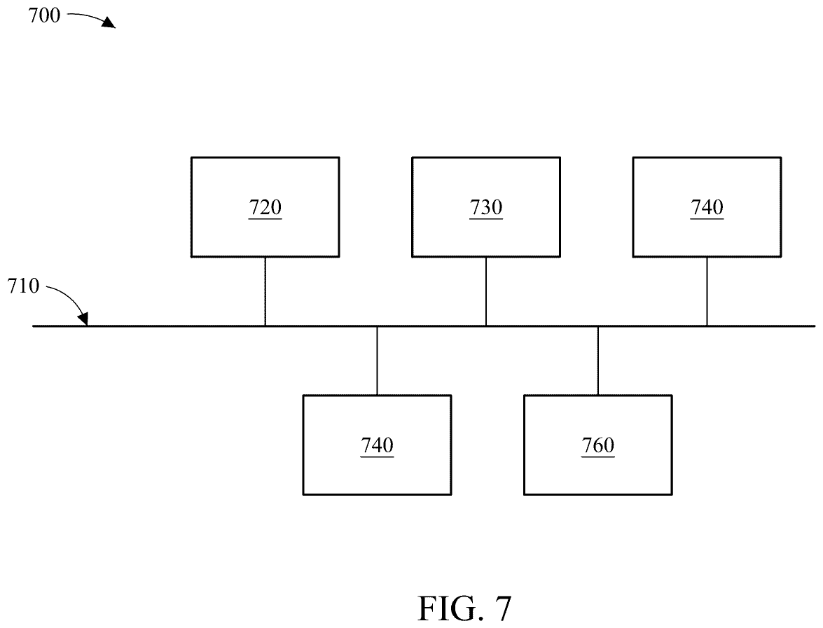

FIG. 7 is a diagram of example components of a device 700 described herein. In some implementations, one or more of the semiconductor processing tools 102-114 and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

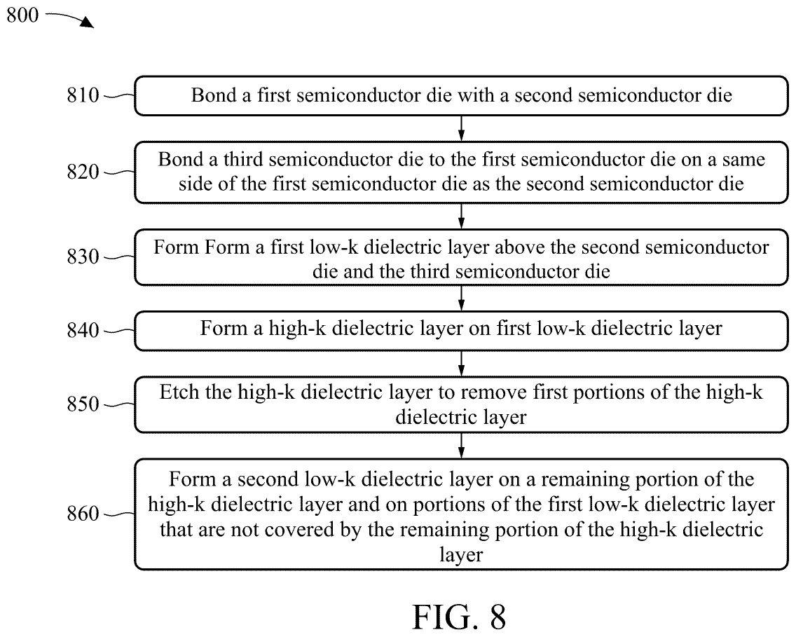

FIG. 8 is a flowchart of an example process 800 associated with forming a semiconductor die package described herein. In some implementations, one or more process blocks of FIG. 8 are performed by one or more semiconductor processing tools (e.g., one or more of the semiconductor processing tools 102-114). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include bonding a first semiconductor die with a second semiconductor die (block 810). For example, one or more of the semiconductor processing tools 102-114 may bond a first semiconductor die 202 with a second semiconductor die 204a, as described above.

As further shown in FIG. 8, process 800 may include bonding a third semiconductor die to the first semiconductor die on a same side of the first semiconductor die as the second semiconductor die (block 820). For example, one or more of the semiconductor processing tools 102-114 may bond a third semiconductor die 204b to the first semiconductor die 202 on a same side of the first semiconductor die 202 as the second semiconductor die 204a, as described above.

As further shown in FIG. 8, process 800 may include forming a first low-k dielectric layer above the second semiconductor die and the third semiconductor die (block 830). For example, one or more of the semiconductor processing tools 102-114 may form a first low-k dielectric layer 238 above the second semiconductor die 204a and the third semiconductor die 204b, as described above.

As further shown in FIG. 8, process 800 may include forming a high-k dielectric layer on the first low-k dielectric layer (block 840). For example, one or more of the semiconductor processing tools 102-114 may form a high-k dielectric layer 254 on the first low-k dielectric layer 238, as described above.

As further shown in FIG. 8, process 800 may include etching the high-k dielectric layer to remove first portions of the high-k dielectric layer (block 850). For example, one or more of the semiconductor processing tools 102-114 may etch the high-k dielectric layer to remove first portions of the high-k dielectric layer, as described above.

As further shown in FIG. 8, process 800 may include forming a second low-k dielectric layer on a remaining portion of the high-k dielectric layer and on portions of the first low-k dielectric layer that are not covered by the remaining portion of the high-k dielectric layer (block 860). For example, one or more of the semiconductor processing tools 102-114 may form a second low-k dielectric layer 242 on a remaining portion of the high-k dielectric layer 254 and on portions of the first low-k dielectric layer 238 that are not covered by the remaining portion of the high-k dielectric layer 254, as described above.

Process 800 may include additional implementations, such as any single implementation or any combination of implementations described below and/or in connection with one or more other processes described elsewhere herein.

In a first implementation, etching the high-k dielectric layer 254 includes etching the high-k dielectric layer 254 to remove the portions of the high-k dielectric layer 254 over the first semiconductor die 204a and the second semiconductor die 204b, where the remaining portion of the high-k dielectric layer 254 is located between the second semiconductor die 204a and the third semiconductor die 204b.

In a second implementation, alone or in combination with the first implementation, forming the high-k dielectric layer 254 includes forming the high-k dielectric layer 254 of at least one of a strontium titanate (SrTiOₓ), a barium titanate (BaTiOₓ), a barium strontium Titanate (BaSrTiOₓ), or a lead zirconate titanate (PbZrTiO₃).

In a third implementation, alone or in combination with one or more of the first and second implementations, forming the high-k dielectric layer 254 includes forming the high-k dielectric layer 254 using a low temperature chemical vapor deposition technique.

In a fourth implementation, alone or in combination with one or more of the first through third implementations, forming the high-k dielectric layer 254 includes forming the high-k dielectric layer 254 using a laser chemical vapor deposition technique.

In a fifth implementation, alone or in combination with one or more of the first through fourth implementations, forming the high-k dielectric layer 254 includes depositing a liquid phase high-k polymer material at room temperature, and curing the liquid phase high-k polymer material to form the high-k dielectric layer 254.

In a sixth implementation, alone or in combination with one or more of the first through fifth implementations, a portion of the first low-k dielectric layer 238 below the remaining portion of the high-k dielectric layer 254, a portion of the second low-k dielectric layer 242 above the high-k dielectric layer 254, and the high-k dielectric layer 254 correspond to a dielectric waveguide structure 252 between the first semiconductor die 204a and the second semiconductor die 204b.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, semiconductor dies in a WoW semiconductor die package may communicate through a dielectric waveguide. The dielectric waveguide may include a high dielectric constant (high-k) core layer that is sandwiched by low dielectric constant (low-k) cladding layers. The difference in dielectric constants of the high-k core layer and the low-k cladding layers provides a relatively low critical angle for achieving total internal reflections in the high-k core layer, thereby allowing coupling of electromagnetic signal modes in the dielectric waveguide. Thus, the combination of WOW semiconductor die package techniques described herein and the dielectric waveguide described herein may enable increased inter-die communication bandwidth (e.g., approximately 10 gigahertz (GHz) bandwidth or greater) while achieving a reduced footprint and increased density for semiconductor die packages. The increased inter-die communication bandwidth may support high-speed and/or high-bandwidth applications, such as data center communications, millimeter wave telecommunications (e.g., fifth generation (5G) telecommunications, sixth generation (6G) telecommunications), autonomous driving, IoT, and/or artificial intelligence, among other examples.

As described in greater detail above, some implementations described herein provide a semiconductor die package. The semiconductor die package includes a first semiconductor die. The semiconductor die package includes a second semiconductor die above the first semiconductor die and bonded with the first semiconductor die at a bonding interface. The semiconductor die package includes a third semiconductor die above the first semiconductor die and bonded with the first semiconductor die at the bonding interface. The semiconductor die package includes a dielectric waveguide structure, between the second semiconductor die and the third semiconductor die, comprising, a first dielectric layer a second dielectric layer on the first dielectric layer a third dielectric layer on the second dielectric layer, where a dielectric constant of the second dielectric layer is greater relative to a dielectric constant of the first dielectric layer and a dielectric constant of the third dielectric layer.

As described in greater detail above, some implementations described herein provide a method. The method includes bonding a first semiconductor die with a second semiconductor die. The method includes bonding a third semiconductor die to the first semiconductor die on a same side of the first semiconductor die as the second semiconductor die. The method includes forming a first low-k dielectric layer above the second semiconductor die and the third semiconductor die. The method includes forming a high-k dielectric layer on the first low-k dielectric layer. The method includes etching the high-k dielectric layer to remove first portions of the high-k dielectric layer. The method includes forming a second low-k dielectric layer on a remaining portion of the high-k dielectric layer and on portions of the first low-k dielectric layer that are not covered by the remaining portion of the high-k dielectric layer.

As described in greater detail above, some implementations described herein provide a semiconductor die package. The semiconductor die package includes a first semiconductor die. The semiconductor die package includes a second semiconductor die above the first semiconductor die and bonded with the first semiconductor die at a bonding interface. The semiconductor die package includes a third semiconductor die above the first semiconductor die and bonded with the first semiconductor die at the bonding interface, where the second semiconductor die and the third semiconductor die are side by side in the semiconductor die package. The semiconductor die package includes a dielectric waveguide structure, between the second semiconductor die and the third semiconductor die, comprising, a first low-k dielectric layer a high-k dielectric layer on the first low-k dielectric layer a second low-k dielectric layer on the high-k dielectric layer, where the second low-k dielectric layer extends along sides of the high-k dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a first semiconductor die with a second semiconductor die;
bonding a third semiconductor die to the first semiconductor die on a same side of the first semiconductor die as the second semiconductor die;
forming a first low dielectric constant (low-k) dielectric layer above the second semiconductor die and the third semiconductor die;
forming a high dielectric constant (high-k) dielectric layer on the first low-k dielectric layer;
etching the high-k dielectric layer to remove first portions of the high-k dielectric layer; and
forming a second low-k dielectric layer on a remaining portion of the high-k dielectric layer and on portions of the first low-k dielectric layer that are not covered by the remaining portion of the high-k dielectric layer.

2. The method of claim 1, wherein etching the high-k dielectric layer comprises:
etching the high-k dielectric layer to remove the first portions of the high-k dielectric layer,
wherein the remaining portion of the high-k dielectric layer is located between the second semiconductor die and the third semiconductor die.

3. The method of claim 1, wherein forming the high-k dielectric layer comprises:
forming the high-k dielectric layer of at least one of:
a strontium titanate,
a barium titanate,
a barium strontium titanate, or
a lead zirconate titanate.

4. The method of claim 1, wherein forming the high-k dielectric layer comprises:
forming the high-k dielectric layer using a low temperature chemical vapor deposition technique.

5. The method of claim 1, wherein forming the high-k dielectric layer comprises:
forming the high-k dielectric layer using a laser chemical vapor deposition technique.

6. The method of claim 1, wherein forming the high-k dielectric layer comprises:
depositing a liquid phase high-k polymer material at room temperature; and
curing the liquid phase high-k polymer material to form the high-k dielectric layer.

7. The method of claim 1, wherein a portion of the first low-k dielectric layer below the remaining portion of the high-k dielectric layer, a portion of the second low-k dielectric layer above the high-k dielectric layer, and the high-k dielectric layer correspond to a dielectric waveguide structure between the second semiconductor die and the third semiconductor die, and
wherein the dielectric waveguide structure comprises respective pluralities of tapered regions at opposing ends of the dielectric waveguide structure.

8. A method, comprising:
forming a first semiconductor die including a device region and an interconnect region;
bonding a second semiconductor die and a third semiconductor die to a same side of the first semiconductor die;
forming a first dielectric layer around the second semiconductor die and the third semiconductor die;
forming a plurality of first conductive structures through the first dielectric layer to a surface of the first semiconductor die; and
forming a second dielectric layer over the first dielectric layer and the plurality of first conductive structures.

9. The method of claim 8, wherein the plurality of first conductive structures extends to a plurality of conductive pads of the first semiconductor die.

10. The method of claim 9, wherein the first semiconductor die comprises a plurality of via structures in contact with the plurality of conductive pads.

11. The method of claim 8, further comprising:
forming a plurality of second conductive structures over the plurality of first conductive structures.

12. The method of claim 11, wherein the plurality of second conductive structures extends through the second dielectric layer.

13. The method of claim 8, further comprising:
forming a third dielectric layer over the second dielectric layer and the plurality of first conductive structures,
wherein a width of the third dielectric layer is less than a width of the second dielectric layer.

14. The method of claim 13, further comprising:
forming a fourth dielectric layer over the third dielectric layer and between the plurality of first conductive structures,
wherein a width of the fourth dielectric layer is less than a width of the third dielectric layer.

15. A method, comprising:
providing a first semiconductor die having a device region and an interconnect region;
bonding a second semiconductor die and a third semiconductor die to a same side of the first semiconductor die;
forming a dielectric layer over and around the second semiconductor die and the third semiconductor die;
forming a plurality of through dielectric via (TDV) structures in the dielectric layer that connect with the interconnect region of the first semiconductor die;
forming a first low dielectric constant (low-k) dielectric layer over the dielectric layer;
forming a high dielectric constant (high-k) dielectric layer over the first low-k dielectric layer; and
forming a second low-k dielectric layer over the high-k dielectric layer.

16. The method of claim 15, wherein the high-k dielectric layer has a dielectric constant at least ten times greater than the first low-k dielectric layer and the second low-k dielectric layer.

17. The method of claim 15, further comprising:
forming conductive structures in the first low-k dielectric layer that connect with the plurality of TDV structures.

18. The method of claim 15, wherein the second semiconductor die and the third semiconductor die are side-by-side on the same side of the first semiconductor die.

19. The method of claim 15, wherein the high-k dielectric layer comprises at least one of:
a titanium dioxide,
a barium titanate,
a strontium titanate, or
a lead zirconate titanate.

20. The method of claim 15, wherein each of the plurality of TDV structures comprises copper, gold, or ruthenium.
